(19) United States
(12) Patent Application Publication
(10) Pub. No.: US 2026/0016533 A1
(43) Pub. Date: Jan. 15, 2026

(54) TEST INTERCONNECT WITH INTEGRATED LOOPBACKS

(71) Applicant: Essai, Inc., San Jose, CA (US)

(72) Inventors: James HASTINGS, Chandler, AZ (US); Nader Nasser ABAZARNIA, Chandler, AZ (US); Quaid Joher FURNITUREWALA, McKinney, TX (US); Rolf NEUWEILER, Magstadt (DE); Juergen SERRER, Stuttgart (DE); Joe XIAO, Chandler, AZ (US)

(21) Appl. No.: 19/200,290

(22) Filed: May 6, 2025

Related U.S. Application Data
(63) Continuation-in-part of application No. 18/882,549, filed on Sep. 11, 2024.
(60) Provisional application No. 63/670,044, filed on Jul. 11, 2024.

(51) Int. Cl. G01R 31/28

(52) U.S. Cl. CPC G01R 31/2889

(57) ABSTRACT

Test interconnect systems and methods are described. In one example, a test interconnect includes. A device under test (DUT) interface for connecting to a DUT; a load board interface for connecting to a load board; a circuitized component including an integrated loopback for self-test or self-communication of the DUT; and one or more conductive paths for connecting the DUT to the load board.

### CROSS-REFERENCE TO RELATED APPLICATIONS

This application is a continuation in part of U.S. Application titled “TEST INTERCONNECT WITH CONDUCTIVE PLANES AND COMPONENTS FOR POWER INTEGRITY AND THERMAL MANAGEMENT,” having application Ser. No. 18/882,549, filed on Sep. 11, 2024, and claims the benefit of U.S. Provisional patent application titled, “TEST INTERCONNECT WITH CONDUCTIVE PLANES AND COMPONENTS FOR POWER INTEGRITY AND THERMAL MANAGEMENT,” filed on Jul. 11, 2024, and having Ser. No. 63/670,044. The subject matter of these related applications is hereby incorporated herein by reference.

### BACKGROUND

### Field of the Various Embodiments

This application relates to techniques for reliable test tooling for packaged integrated circuits (IC) devices, and more specifically, to test interconnects with integrated loopbacks for a device under test. The techniques also include using conductive planes and components for power integrity and thermal management.

### Description of the Related Art

Reliable test tooling for packaged integrated circuits (IC) devices often use testing sockets. Testing sockets can provide temporary connections to a device under test (DUT) and testing equipment. The testing equipment can perform one or more tests on the DUT while the testing socket acts as a temporary interconnect.

Testing sockets can include structures to hold the DUT in place for testing the DUT using a test circuit. Some DUTs perform a self-test function or other types of functions where one input/output connection of the DUT transmits and/or receives from another input/output connection of the DUT. The connection from one input/output connection of the DUT to another input/output connection of the DUT can be referred to as a loopback path or loopback. However, one drawback of existing test systems (including the testing socket, load board, and tester) is that traditional testing systems do not provide loopback paths in locations near the DUT. Instead, loopback paths are relatively long, resulting in parasitic effects. For example, traditional loopback circuits connect between two contacts of the DUT using a path that passes through the testing socket, the load board, and a circuit external to the load board. The long loopback paths of traditional systems often cause parasitic effects from undesirable resistances, capacitances, and inductances that exist within the loopback path. These issues can also cause signal degradation, interference, propagation delays, and other issues during device testing. Testing the DUT can also include providing a positive supply voltage, sometimes referred to as a drain voltage “V_{DD}” to power the DUT. Testing the DUT can also include providing a ground (or negative voltage), sometimes referred to as a source voltage “V_{SS},” to the DUT. However, one drawback of existing test systems (including the testing socket, load board, and tester) is that there is no provision to accurately detect V_{DD} in locations near the DUT. Instead, existing technologies measure voltage from the load board side of the socket. This can limit the bandwidth of voltage measurements and cause changes in the voltage at the DUT due to the parasitic losses of a spring probe.

Another drawback of existing test sockets is that these test sockets are limited in their ability to improve “power integrity.” When power integrity suffers, excessive current fluctuations and voltage fluctuations can cause failures that invalidate testing as well as cause damage to the DUT, test socket, and load board. For example, localized current spikes can be caused by certain test vectors during new product development and testing, which can cause electrical damage to the DUT, socket, and load board. In addition, localized hot-spots can be caused by these current spikes that cause heat damage to the DUT, socket, and load board.

As the foregoing illustrates, what is needed in the art is testing interconnects and corresponding load board circuitry that can reduce signal degradation and interference from resistive, capacitive, and/or inductive losses in loopback paths for self-communication functions of a DUT. A further need includes testing interconnects and corresponding load board circuitry that can enable accurate detection of voltage near the DUT while improving power integrity by reducing current fluctuations.

### SUMMARY

One embodiment of the present disclosure sets forth a system that includes a DUT interface for connecting to a DUT; a load board interface for connecting to a load board; a circuitized component including one or more integrated loopbacks for self-test or self-communication of the DUT; and one or more conductive paths for connecting the DUT to the load board. In various embodiments, the circuitized component includes a circuit board and/or an elastomer-based component.

Further embodiments include configuring a test interconnect to include a device under test (DUT) interface for connecting to a DUT, a load board interface for connecting to a load board, and one or more integrated loopbacks for self-test or self-communication of the DUT; applying a supply voltage and a test pattern that causes the DUT to perform a loopback functionality or a self-test functionality; and performing a management action based on a result of the loopback functionality or the self-test functionality.

At least one technical advantage of the disclosed techniques relative to the prior art is that the disclosed techniques provide more accurate DUT self-test and other self-communication functions for testing interconnects. Another technical advantage is a reduction of resistive, capacitive, and/or inductive losses in loopback paths for self-test functions and other self-communication functions of a DUT. The reduction in resistive, capacitive, and/or inductive losses provides higher signal quality and reduced interference in the loopback path, which provide an improved ability to test transmit and receive functions of a DUT. With the disclosed techniques, a more accurate measurement of power supply voltage is obtained. Another technical advantage is that power supply integrity is increased. The improved power supply integrity reduces the likelihood of electrical damage, heat damage, and/or other damage to the DUT, the test socket, and the load board during testing. These technical advantages provide one or more technological advancements over prior art approaches.

### BRIEF DESCRIPTION OF THE DRAWINGS

So that the manner in which the above recited features of the various embodiments can be understood in detail, a more particular description of the inventive concepts, briefly summarized above, can be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 is an exploded view of an example test system for power integrity and thermal management, according to various embodiments;

FIG. 2 is a cross-sectional view of a test system, according to various embodiments;

FIG. 3 is a cross-sectional view of another test system, according to various embodiments;

FIG. 4 is a cross-sectional view of another test system, according to various embodiments;

FIG. 5 is a detail view of a portion of a test interconnect assembly, according to various embodiments;

FIG. 6 is a flow diagram of method steps for power management using a test system, according to various embodiments;

FIG. 7 is a flow diagram of method steps for configuring a test system, according to various embodiments;

FIG. 8 is a cross-sectional view of a test system, according to various embodiments;

FIG. 9 is a cross-sectional view of another test system, according to various embodiments;

FIG. 10 is a cross-sectional view of another test system, according to various embodiments;

FIG. 11 is a cross-sectional view of another test system, according to various embodiments; and

FIG. 12 is a flow diagram of method steps for loopback or self-test management using a test system, according to various embodiments.

### DETAILED DESCRIPTION

In the following description, numerous specific details are set forth to provide a more thorough understanding of the various embodiments. However, it will be apparent to one of skilled in the art that the inventive concepts can be practiced without one or more of these specific details.

The described testing systems include interconnect assemblies that hold a DUT in place and perform a test of the DUT. An interconnect assembly provides an integrated loopback from one input/output connection of a DUT to another input/output connection of the DUT within an interconnect component disposed between the DUT and the load board. Generally, the test interconnect assembly can include a socket type structure or any structure that holds the DUT and provides connections to the load board. In some embodiments, the interconnect assembly can include a socket type structure or any structure to hold the DUT, and compressible probes that connect from the DUT to the load board. Testing the DUT can include providing one or more supply voltages (e.g., a positive voltage and/or a negative voltage) and a ground to the DUT, as well as applying a test pattern that causes the DUT to perform a self-test or other self-communication functionality. During a test, the load board and other testing equipment applies a test pattern to the DUT through the interconnect assembly, and monitors voltages, currents, temperatures, and/or other parameters. In some embodiments, an interconnect assembly provides circuit connections from a DUT to testing equipment such as a load board.

One drawback of traditional testing systems is that loopback paths are relatively long, resulting in parasitic effects from undesirable resistances, capacitances, and inductances that cause signal degradation, interference, propagation delays, and/or other issues during device testing. Unlike existing testing systems that provide loopback paths that pass through the load board, the test interconnect assemblies described herein provide a shorter loopback path, for example, that does not extend to or through the load board. The described loopback paths have the capability of providing a less lossy path and/or a path that includes one or more configurable or tunable losses (e.g., resistive, capacitive, and/or inductive losses).

To this end, some embodiments of the described test interconnect assemblies provide a circuitized component disposed between the DUT and the load board, where the circuitized component includes an integrated loopback for DUT self-communication (e.g., loopback) functionalities. In various examples, the circuitized component includes a circuit board component and/or a circuitized elastomer component that provides the integrated loopback. In some embodiments, elastomer contact connectors connect the DUT to the test interconnect assembly (e.g., to the circuitized component or a stiffening plate between the circuitized component and the DUT). In some examples, the circuitized component includes one or more conductive planes and/or passive circuit components such as capacitors, resistors, and/or inductors for the integrated loopback circuit.

A further drawback of existing test systems is that there is no provision to accurately detect supply voltage in locations near the DUT. Unlike existing testing systems that measure voltage from the load board side, the test interconnect assemblies described herein enable DUT-side supply voltage measurements.

To this end, some embodiments of the described test interconnect assemblies include a circuit board on a DUT side of a housing or an elastomer component (e.g., closer to the DUT than the load board). The circuit board includes one or more conductive planes that provide an additional conductive path for the one or more supply voltages for the DUT. Furthermore, some embodiments of the described test interconnect assemblies provide for DUT-side testing using Kelvin probes and other probes that connect to the DUT-side circuit board in various testing locations that can be inside or outside a device footprint. Accordingly, the described testing systems provide more accurate power supply measurements than prior technologies and also increase power supply integrity.

Another drawback of existing test sockets is their inability to improve power integrity, often resulting in voltage and current spikes as well as heat damage. Poor power integrity can cause damage to the DUT, test socket, and load board. Unlike existing testing systems that provide poor power integrity, the conductive planes of the DUT-side circuit board, and other components of the test interconnect assemblies, provide improved power integrity by providing additional conductive paths for source power (e.g., in addition to paths through the compressible probes). The additional conductive paths reduce current spikes and improve heat dissipation. Accordingly, the described testing systems reduce the likelihood of electrical damage, heat damage, and/or other damage to the DUT, the test socket, and the load board during testing. A more detailed description is provided through a discussion of the following figures.

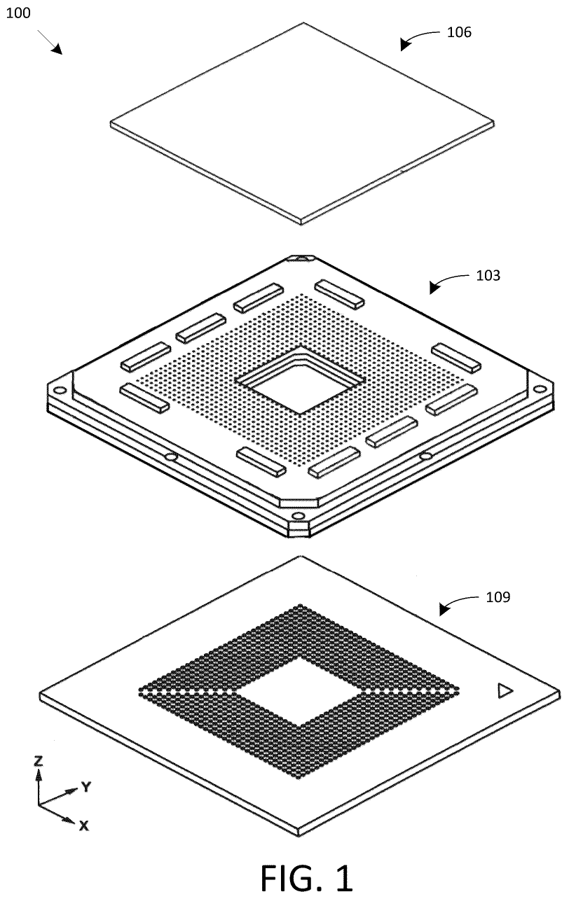

FIG. 1 is an exploded view of an example test system 100, according to various embodiments. Test system 100 includes, without limitation, a test interconnect assembly 103, a DUT 106, and a load board 109. The test interconnect assembly 103 includes, without limitation, a DUT interface for connecting to the DUT 106, a load board interface for connecting to the load board 109, a circuitized component (not shown) that includes one or more integrated loopbacks for self-test or self-communication of the DUT, and one or more conductive paths for connecting the DUT 106 to the load board 109. The conductive paths can include separate components such as probes that pass through the circuitized component and/or integrated conductive paths such as traces that extend through the circuitized component from a DUT side to a load board side. The DUT side surface of the test interconnect assembly 103 (and/or circuitized component) can refer to a surface of the test interconnect assembly 103 (and/or circuitized component) that is closer to the DUT 106 as compared to the load board 109. The load board side of the test interconnect assembly 103 can refer to a surface of the test interconnect assembly 103 (and/or circuitized component) that is closer to the load board 109 as compared to the DUT 106.

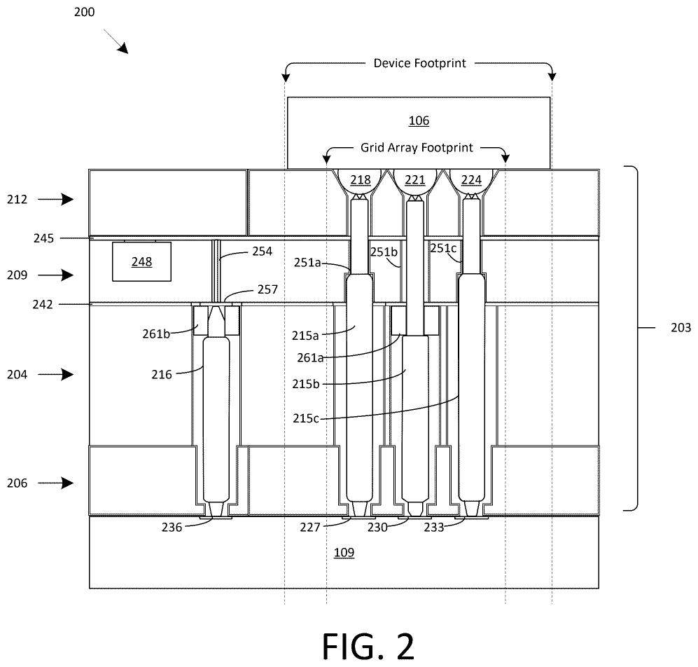

Further embodiments include techniques for using conductive planes and components such as Kelvin probes for power integrity and thermal management, for example, as described with respect to FIGS. 2-7. Techniques that are described with respect to a particular Figure are combinable with techniques and features of the other Figures. For example, techniques for providing conductive planes and components such as Kelvin probes for power integrity and thermal management are combinable with techniques for providing integrated loopbacks.

FIG. 2 is a cross-sectional view of a test system 200, according to various embodiments. Test system 200 is an example of the test system 100. The test system 200 includes, without limitation, a test interconnect assembly 103, a DUT 106, and a load board 109. The test interconnect assembly 203 includes, without limitation, a main housing structure 204, a cover plate 206, a circuit board 209, a stiffening plate 212, one or more compressible probes 215a, 215b, and 215c (collectively, “compressible probes 215”), and one or more measurement compressible probes 216. The test interconnect assembly 203 can include any number of compressible probes 215, and any number of measurement compressible probes 216. The DUT 106 includes, without limitation, a supply voltage contact 218, a signal contact 221, a ground contact 224, and other components. The load board 109 includes, without limitation, a supply voltage contact 227, a signal contact 230, a ground contact 233, a supply voltage measurement contact 236, and other components. The circuit board 209 includes, without limitation, one or more ground layers 242, one or more supply voltage layers 245, one or more capacitors 248, one or more hollow vias 251a, 251b, 251c (collectively, “hollow vias 251”), one or more vias 254, and one or more supply voltage measurement contacts 257. The test interconnect assembly 103 also includes one or more probe spacers 261a, 261b (collectively, “probe spacers 261”).

The DUT 106 includes a number of contacts arranged in a grid array. A grid array includes a pattern of any kind of contacts. For example, a grid array can include a ball grid array of solder ball contacts, a land grid array of contact pads, a pin grid array of pin contacts, and so on. The contacts of the DUT 106 can be referred to as DUT contacts. The grid array of the DUT 106 can be referred to as a DUT grid array. In FIG. 2, the DUT contacts are shown as solder ball contacts. And although only supply voltage contact 218, signal contact 221, and ground contact 224 are shown in FIG. 2, the DUT 106 can include any number of supply voltage contacts 218, any number of signal contacts 221, and any number of ground contacts 224. For example, some DUTs 106 can include one or more negative voltage contacts.

The load board 109 includes a number of contacts arranged in a grid array or contact array. The grid array of the load board 109 can be referred to as a load board grid array. In FIG. 2, the load board contacts are shown as contact pads. Although only one supply voltage contact 227, one signal contact 230, and one ground contact 233 are shown, the load board 109 can include any number of supply voltage contacts 227, any number of signal contacts 230, any number of ground contacts 233, and any number of supply voltage measurement contacts 236. Some load boards 109 include one or more negative voltage contacts (not shown).

The main housing structure 204 holds or houses the compressible probes 215. To this end, the test interconnect assembly 203 includes probe holes or cavities that extend through the main housing structure 204, the cover plate 206, the circuit board 209, and the stiffening plate 212. In FIG. 2, the probe holes and/or other components of the test interconnect assembly 203 hold the compressible probes 215 in an orientation that is orthogonal to the distal (e.g., closer to the DUT 106) and proximal (e.g., closer to the load board 109) surfaces of the main housing structure 204. However, in other examples, the probe holes can hold the compressible probes 215 at a predetermined angle. The angle of the compressible probes 215 can be uniform, or the angle can be different for each of the compressible probes 215. In some examples, the probe holes (and probe spacers) of the main housing structure 204 are sized and shaped to create a coaxial transmission path with a desired impedance to maximize signal transmission. In some examples, a predetermined or desired impedance can be 50 ohms (or any other desired impedance) to maximize signal transmission. The main housing structure 204 can be anodized, and the desired impedance can be achieved based on anodization parameters including, without limitation, use of a particular material, a particular thickness, and so on.

The main housing structure 204 can be constructed of a dielectric material such as plastic. In other examples, the main housing structure 204 can be constructed of a conductive material such as aluminum. In examples where the main housing structure 204 is constructed of a conductive material, the main housing structure 204 can be grounded by a connection to a compressible probe such as the compressible probe 215c. The main housing structure 204 can be anodized to prevent shorting other compressible probes 215. The compressible probe 215c connects between the ground contact 233 of the load board 109 and the ground contact 224 of the DUT 106. The compressible probe 215c can connect the main housing structure 204 to a ground net of an overall circuit that includes the DUT 106, the load board 109, and the test interconnect assembly 103. The compressible probe 215c can connect the main housing structure 204 to a ground net using a physical connection of the compressible probe 215c to a ground plane or ground layer 242 of the circuit board 209. The ground layer 242 of the circuit board 209 can make contact with the main housing structure 204. In other examples, a probe hole of the main housing structure 204 can be sized to make direct contact with the compressible probe 215c, or a conductive spacer that fits around the compressible probe 215c can connect the compressible probe 215c to the main housing structure 204. The grounding of the main housing structure 204 can create a coaxial structure in combination with the various compressible probes 215. The compressible probe 215b carries a signal between the load board 109 and the DUT 106. Each of the compressible probes 215a and 215b, and the measurement compressible probe 216 can be surrounded by an air gap and other dielectric materials. The dielectric materials can include the anodization of the main housing structure 204. The air gap and other dielectric materials can provide a desired impedance to maximize signal transmission. The air gap and other dielectric materials can be surrounded by a ground provided using the grounded main housing structure 204. The anodization of the main housing structure 204 provides at least a portion of the desired impedance based on anodization parameters.

Where the main housing structure 204 is constructed of a dielectric material, the probe holes can have a conductive sheath or coating that forms a coaxial structure. In some cases, the main housing structure 204 is constructed as a single integrated unit with the circuit board 209. The conductive sheath or coating can be grounded by making contact with a ground layer 242 of the circuit board 209. For example, the compressible probe 215b can carry a signal between the load board 109 and the DUT 106. Each of the compressible probes 215a and 215b, and the measurement compressible probe 216 can be surrounded by an air gap and other dielectric materials. The dielectric materials can include anodization over a conductive portion of the sheath or coating. The air gap and other dielectric materials can provide a desired impedance to maximize signal transmission. The air gap and other dielectric materials can be surrounded by a ground provided using the grounded conductive sheath or coating. The anodization of the sheath or coating provides at least a portion of the desired impedance based on anodization parameters.

The cover plate 206 interfaces with the load board 109. The cover plate 206 retains a proximal portion of the compressible probes 215. As a result, the cover plate 206 can be referred to as a compressible probe retention plate or a load board interface of the test interconnect assembly 103. The cover plate 206 can be constructed of a dielectric material such as plastic. In other examples, the cover plate 206 is constructed of a conductive material such as aluminum. In examples where the cover plate 206 is constructed of a conductive material, the cover plate 206 can be grounded by a connection to a compressible probe such as the compressible probe 215c. The proximal cover plate 206 can be anodized to prevent shorting other compressible probes 215. The compressible probe 215c connects the cover plate 206 to a ground net using a physical connection of the compressible probe 215c to a ground plane or ground layer 242 of the circuit board 209. A probe hole of the cover plate 206 can be sized to make direct contact with the compressible probe 215c, or a conductive spacer that fits around the compressible probe 215c can connect the compressible probe 215c to the cover plate 206. In examples where both the main housing structure 204 and the cover plate 206 are conductive, the main housing structure 204 can be grounded, and the cover plate 206 can be grounded by making contact with the main housing structure 204. The grounding of the cover plate 206 can create a coaxial structure in combination with the various compressible probes 215.

The cover plate 206 can provide a portion of the probe holes. The portion of the probe holes provided using the cover plate 206 can be sized and shaped to create a coaxial transmission path with a desired impedance to maximize signal transmission. In some examples, a predetermined or desired impedance can be 50 ohms (or another impedance) to maximize signal transmission. The cover plate 206 can be anodized, and a desired impedance can be achieved based on anodization parameters. In some embodiments, structures and functionalities described with respect to the main housing structure 204, the cover plate 206, and/or circuit board 209 can be provided using a circuitized elastomer component. The circuitized elastomer component can include integrated conductive paths that include a conductive powder that becomes conductive when compressed. In some embodiments, the conductive powder can include nickel or another ferrous and/or conductive metal and can be plated with a conductive metal such as silver or gold. In some embodiments, the integrated conductive paths includes at least a portion of an integrated loopback path.

The circuit board 209 can include a printed circuit board or another type of circuit board. The circuit board 209 can be composed using fiberglass, ceramics, polyimide or another material. The circuit board 209 can have a composite construction that includes, without limitation, one or more dielectric material and one or more conductive layers or planes. Each conductive layer includes one or more conductive traces or areas. The circuit board 209 can include any number of ground layers 242. The circuit board 209 can include any number of supply voltage layers 245. The circuit board 209 can include any number of capacitors 248. The circuit board 209 can include any number of hollow vias 251. In some embodiments, the circuit board 209 includes at least a portion of an integrated loopback path.

In FIG. 2, the capacitors 248 are shown to be embedded within a surface of the circuit board 209. The material can be etched, cut out, or otherwise removed in the area where a capacitor 248 is to be embedded. The circuit board 209 can include cutouts or etched areas in an upper layer closer to the DUT 106 and cutouts or etched areas in a lower layer closer to the main housing structure 204. The cutouts or etched areas can accommodate the capacitors 248. However, in some cases a capacitor 248 can be attached to a surface of a circuit board 209. In that case, the stiffening plate 212 includes a cutout for the capacitor 248, or the stiffening plate 212 can be absent. The capacitors 248 can stabilize supply voltage levels supplied using the supply voltage layer 245 and traces. The capacitors 248 can also perform circuit functions in conjunction with the load board 109 and/or the DUT 106.

The circuit board 209 provides a portion of the probe holes of the test interconnect assembly 103. A probe hole can be provided using a hollow conductive via that is shaped to accommodate a portion of a compressible probe 215. Conductive vias through the circuit board 209 concentric to the grid array of the DUT 106 can be selectively connected to the conductive layers of the circuit board 209. However, in some examples, the via is not connected to any conductive layers. For example, in the shown configuration, the via for the compressible probe 215b is not connected to any conductive layer because there is no circuit board 209 layer corresponding to the signal that passes through the compressible probe 215b.

A portion of the probe hole for the compressible probe 215a is provided using a hollow via 251. The hollow via 251a can be plated or otherwise include a conductive material. The hollow via 251a provides a conductive connection to one or more supply voltage layers 245 of the circuit board 209. The connection to the supply voltage layers 245 of the circuit board 209 enables heat dissipation and additional supply voltage conductive paths in addition to the compressible probe 215a. Relative to previous technologies, this improves power integrity, reduces current fluctuations, and improves heat dissipation.

A portion of the probe hole for the compressible probe 215b is provided using a hollow via 251b of the circuit board 209. The hollow via 251b can be plated or otherwise include a conductive material that extends through the circuit board 209, or the hollow via 254 can refer to a hole drilled through the circuit board 209. A probe spacer 261a holds the compressible probe 215b concentric with the probe hole and the signal contact 221. The probe spacer 261a can include a shape, size, and dielectric material that is selected to provide a desired impedance that maximizes signal transmission through the compressible probe 215b.

A portion of the probe hole for the compressible probe 215c is provided using a hollow via 251c. The hollow via 251c can be plated or otherwise include a conductive material that extends through the circuit board 209. The hollow via 251c provides a conductive connection to one or more ground layers 242 of the circuit board 209. The connection to the ground layers 242 of the circuit board 209 enables heat dissipation and additional conductive paths in addition to the compressible probe 215c. Relative to previous technologies, this improves power integrity, reduces current fluctuations, and improves heat dissipation.

The circuit board 209 includes a supply voltage measurement contact 257. The compressible probe 216 connects to the supply voltage measurement contact 236 of the load board 109 and to the supply voltage measurement contact 257 of the circuit board 209. The circuit board 209 can include any number of supply voltage measurement contacts 257 to read the supply voltage in multiple locations. The supply voltage measurement contacts 257 enable accurate measurement of supply voltage as read from one or more locations nearer to the DUT 106 than the load board 109. A conductive via 254 connects the supply voltage measurement contact 257 to a supply voltage layer 245 of the circuit board 209. A probe spacer 261b holds the compressible probe 216 concentric with the probe hole and the via 254. The probe spacer 261b can include a shape, size, and/or dielectric material that is selected to provide a desired impedance.

The circuit board 209 retains a distal portion of the compressible probes 215 and measurement compressible probes 216. In some examples, the circuit board 209 can be too flexible to effectively hold the compressible probes 215. The stiffening plate 212 provides rigidity to hold the circuit board 209 solidly in place against the pressure exerted by the compressible robes 215. However, in other cases the circuit board 209 includes a rigid material and/or includes sufficient layers to prevent flexion based on the pressure exerted by the compressible robes 215. Where the circuit board 209 has sufficient strength and rigidity to prevent flexion based on the pressure exerted by the compressible robes 215, the stiffening plate 212 can be omitted. The circuit board 209 the stiffening plate 212, and/or a floating plate (not shown) can provide a DUT interface of the test interconnect assembly 103. The stiffening plate 212 can include a grid array alignment aid for the grid array of the DUT 106. For example, the stiffening plate 212 can include indents that can receive solder balls, pins, and other contacts of the DUT 106. The stiffening plate 212 can additionally or alternatively include one or more raised elements that make contact with a periphery of the DUT 106. In some examples, the stiffening plate 212 does not include a grid alignment aid, and a floating plate can provide a suspended grid alignment aid between the stiffening plate 212 and the DUT 106. The floating plate can include indents that can receive solder balls, pins, and other contacts to interface with the DUT 106. The floating plate can be suspended using springs or another compressible suspension device that can enable even contact between the contacts of the DUT 106 and the compressible probes 215. In examples where the stiffening plate 212 is omitted a floating plate can provide a compressible-suspended grid alignment aid between the circuit board 209 and the DUT 106.

A distal portion of each of the compressible probes 215 and measurement compressible probes 216 can be aligned concentric with the grid array of the DUT 106. A proximal portion of each of the compressible probes can be aligned concentric with the grid array of the load board 109. The compressible probe 215a connects the supply voltage contact 218 of the DUT 106 to the supply voltage contact 227 of the load board 109. The compressible probe 215a provides additional conductive paths and heat dissipation by connecting to the supply voltage layer 245 of the circuit board 209. This circuit connection can be referred to as a supply voltage net. The compressible probe 215b connects the signal contact 221 of the DUT 106 to the signal contact 230 of the load board 109. This circuit connection can be referred to as a signal net. The compressible probe 215c connects the ground contact 224 of the DUT 106 to the ground contact 233 of the load board 109. The compressible probe 215c provides additional conductive paths and heat dissipation by connecting to the ground layer 242 of the circuit board 209. This circuit connection can be referred to as a ground net.

The compressible probe 216 connects the supply voltage measurement contact 257 of the circuit board 209 to the supply voltage measurement contact 236 of the load board 109. The compressible probe 216 can include a high-bandwidth “Kelvin” type measurement probe. The Kelvin type of probe connection can effectively eliminate current path impedance and temperature effects, thereby enabling more accurate measurement of supply voltage as experienced near the DUT, as compared to measurements through the other compressible probes 215a, 215b, 215c. The supply voltage measurement contact 236 connects to the supply voltage layer 245 of the circuit board 209 using the via 254. Some of the conductive layers of the circuit board 209 extend outside the device footprint of the DUT 106. The compressible probe 216, the capacitor 248, the supply voltage measurement contact 257, and the via 254 can also be located outside the device footprint of the DUT 106. Locating these components outside the device footprint can help provide space and isolation for the Kelvin type of connection to a tester. The connection to the tester can include connecting to a portion of the load board 109 as shown, or connecting a cable to a testing device (not shown) separate from the load board 109. The Kelvin type of connection enables the tester to better measure and control the voltage close to the DUT 106, because the connection can bypass all or a portion of the temperature, resistance, capacitance, and inductance that can affect compressible probes 215a, 215b, 215c.

The test system 200 can perform a test of the DUT 106 once the test interconnect assembly 203 is deployed to provide interconnects between the DUT 106 and the load board 109. The test system 200 applies supply voltage(s) and performs test pattern(s) using the load board 109. The supply voltage(s) and test patterns can pass through all or a subset of the compressible probes 215a, 215b, 215c. Performing test patterns can include inputting analog and/or digital voltage signals to one or more signal nets, reading analog and/or digital voltage signals from the one or more signal nets, and so on. The test system 200 can take power measurements including, without limitation, current measurements, voltage measurements, and other measurements using the measurement compressible probe 216. In some examples, the test system 200 can take temperature measurements using the compressible probe 216 or a temperature sensor device (not shown). The test system 200 can perform a management action such as a power management action or a loopback management action based on the power measurements and temperature measurements. The power management action can include, without limitation, modifying a voltage output, modifying a current output, and disconnecting a power connection.

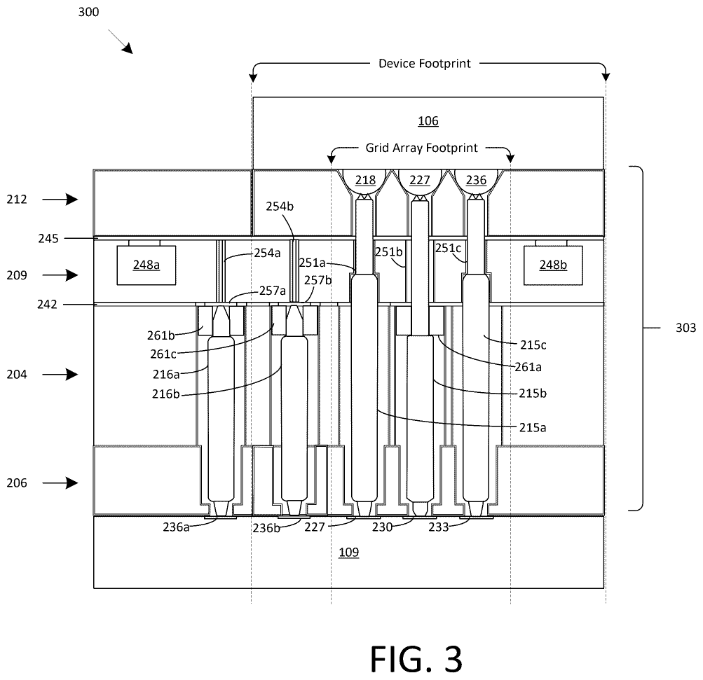

FIG. 3 is a cross-sectional view of a test system 300, according to various embodiments. Test system 300 is an example of a test system 100. The test system 300 shown in FIG. 3 includes, without limitation, a test interconnect assembly 103, a DUT 106, and a load board 109. The test interconnect assembly 303 includes, without limitation, a main housing structure 204, a cover plate 206, a circuit board 209, a stiffening plate 212, one or more compressible probes 215a, 215b, and 215c (collectively, “compressible probes 215”), and one or more measurement compressible probes 216a and 216b (collectively, “measurement compressible probes 216”). The test interconnect assembly 303 can include any number of compressible probes 215, and any number of measurement compressible probes 216. The DUT 106 includes, without limitation, a supply voltage contact 218, a signal contact 221, a ground contact 224, and other components. The load board 109 includes, without limitation, a supply voltage contact 227, a signal contact 230, a ground contact 233, one or more supply voltage measurement contacts 236a and 236b (collectively, “supply voltage measurement contacts 236”), and other components. The circuit board 209 includes, without limitation, one or more ground layers 242, one or more supply voltage layers 245, one or more capacitors 248, one or more hollow vias 251a, 251b, and 251c (collectively, “hollow vias 251”), one or more vias 254a and 254b (collectively vias 254), and one or more supply voltage measurement contacts 257a and 257b (collectively, “supply voltage measurement contacts 257”). The test interconnect assembly 303 can also include one or more probe spacers 261a, 261b, 261c (collectively, “probe spacers 261”).

The DUT 106 includes a number of contacts arranged in a grid array. The DUT contacts are shown as solder ball contacts. The DUT contacts include, without limitation, a supply voltage contact 218, a signal contact 221, and a ground contact 224. And although only three contacts are shown, the DUT 106 can include any number of supply voltage contacts 218, any number of signal contacts 221, and any number of ground contacts 224. Some DUTs 106 can include one or more negative voltage contacts.

The load board 109 includes a number of contacts arranged in a grid array or contact array. The load board contacts are shown as contact pads. The load board contacts include, without limitation, a supply voltage contact 227, a signal contact 230, a ground contact 233, and a supply voltage measurement contact 236. The load board 109 can include any number of supply voltage contacts 227, any number of signal contacts 230, any number of ground contacts 233, and any number of supply voltage measurement contacts 236. Some load boards 109 include one or more negative voltage contacts (not shown).

The main housing structure 204 holds or houses the compressible probes 215. To this end, the test interconnect assembly 303 includes probe holes or cavities that extend through the main housing structure 204, the cover plate 206, the circuit board 209, and the stiffening plate 212. The probe holes and/or other components of the test interconnect assembly 303 can hold the compressible probes 215 in any desired orientation. In some examples, the probe holes (and probe spacers) of the main housing structure 204 are sized and shaped to create a coaxial transmission path with a desired impedance to maximize signal transmission. The main housing structure 204 can be anodized, and the desired impedance can be achieved based on anodization parameters.

The main housing structure 204 can be constructed of a dielectric material such as plastic. In other examples, the main housing structure 204 can be constructed of a conductive material such as aluminum. In examples where the main housing structure 204 is constructed of a conductive material, the main housing structure 204 can be grounded by a connection to a compressible probe such as the compressible probe 215c. The main housing structure 204 can be anodized to prevent shorting other compressible probes 215. The compressible probe 215c connects between the ground contact 233 of the load board 109 and the ground contact 224 of the DUT 106. The compressible probe 215c can connect the main housing structure 204 to a ground net of an overall circuit that includes the DUT 106, the load board 109, and the test interconnect assembly 303. The compressible probe 215c can connect the main housing structure 204 to a ground net using a physical connection of the compressible probe 215c to a ground plane or ground layer 242 of the circuit board 209. The ground layer 242 of the circuit board 209 can make contact with the main housing structure 204. In other examples, a probe hole of the main housing structure 204 can be sized to make direct contact with the compressible probe 215c, or a conductive spacer that fits around the compressible probe 215c can connect the compressible probe 215c to the main housing structure 204. The grounding of the main housing structure 204 can create a coaxial structure in combination with the various compressible probes 215. The compressible probe 215b carries a signal between the load board 109 and the DUT 106. Each of the compressible probes 215a and 215b, and the measurement compressible probe 216 can be surrounded by an air gap and other dielectric materials. The dielectric materials can include the anodization of the main housing structure 204. The air gap and other dielectric materials can provide a desired impedance to maximize signal transmission. The air gap and other dielectric materials can be surrounded by a ground provided using the grounded main housing structure 204. The anodization of the main housing structure 204 provides at least a portion of the desired impedance based on anodization parameters.

In examples where the main housing structure 204 is constructed of a dielectric material, the probe holes can have a conductive sheath or coating that forms a coaxial structure. In some cases, the main housing structure 204 is constructed as a single integrated unit with the circuit board 209. The conductive sheath or coating can be grounded by making contact with a ground layer 242 of the circuit board 209. For example, the compressible probe 215b can carry a signal between the load board 109 and the DUT 106. Each of the compressible probes 215a and 215b, and the measurement compressible probe 216 can be surrounded by an air gap and other dielectric materials. The dielectric materials can include anodization over a conductive portion of the sheath or coating. The air gap and other dielectric materials can provide a desired impedance to maximize signal transmission. The air gap and other dielectric materials can be surrounded by a ground provided using the grounded conductive sheath or coating. The anodization of the sheath or coating provides at least a portion of the desired impedance based on anodization parameters.

The cover plate 206 interfaces with the load board 109. The cover plate 206 retains a proximal portion of the compressible probes 215. As a result, the cover plate 206 can be referred to as a compressible probe retention plate or a load board interface of the test interconnect assembly 303. The cover plate 206 can be constructed of a dielectric material such as plastic. In other examples, the cover plate 206 is constructed of a conductive material such as aluminum. In examples where the cover plate 206 is constructed of a conductive material, the cover plate 206 can be grounded by a connection to a compressible probe such as the compressible probe 215c. The proximal cover plate 206 can be anodized to prevent shorting other compressible probes 215. The compressible probe 215c connects the cover plate 206 to a ground net using a physical connection of the compressible probe 215c to a ground plane or ground layer 242 of the circuit board 209. A probe hole of the cover plate 206 can be sized to make direct contact with the compressible probe 215c, or a conductive spacer that fits around the compressible probe 215c can connect the compressible probe 215c to the cover plate 206. In examples where both the main housing structure 204 and the cover plate 206 are conductive, the main housing structure 204 can be grounded, and the cover plate 206 can be grounded by making contact with the main housing structure 204. The grounding of the cover plate 206 can create a coaxial structure in combination with the various compressible probes 215.

The cover plate 206 can provide a portion of the probe holes. The portion of the probe holes provided using the cover plate 206 can be sized and shaped to create a coaxial transmission path with a desired impedance to maximize signal transmission. The cover plate 206 can be anodized, and a desired impedance can be achieved based on anodization parameters.

The circuit board 209 can include a printed circuit board or another type of circuit board. The circuit board 209 can be composed using fiberglass, ceramics, polyimide or another material. The circuit board 209 can have a composite construction that includes, without limitation, one or more dielectric material and one or more conductive layers or planes. Each conductive layer includes one or more conductive traces or areas. The circuit board 209 can include any number of ground layers 242. The circuit board 209 can include any number of supply voltage layers 245. The circuit board 209 can include any number of capacitors 248. The circuit board 209 can include any number of hollow vias 251.

In the example of FIG. 3, the capacitors 248 include capacitor 248a and capacitor 248b. The capacitor 248a is located outside the device footprint. The capacitor 248b is located inside the device footprint and outside of the grid array footprint. Locating the capacitor 248b inside the device footprint increases the overall number (and density) of capacitors 248 of the circuit board 209. The increased number and density of capacitors 248 can increase power integrity inside the device footprint. The capacitors 248 are shown to be embedded within a surface of the circuit board 209. The material can be etched, cut out, or otherwise removed in the area where a capacitor 248 is to be embedded. The circuit board 209 can include cutouts or etched areas in an upper layer closer to the DUT 106 and cutouts or etched areas in a lower layer closer to the main housing structure 204. The cutouts or etched areas can accommodate the capacitors 248. However, in some cases a capacitor 248 can be attached to a surface of a circuit board 209. In that case, the stiffening plate 212 can include a cutout for the capacitor 248, or the stiffening plate 212 can be absent. The capacitors 248 can be used to stabilize supply voltage levels supplied using the supply voltage layer 245 and traces. The capacitors 248 can also be used to perform circuit functions in conjunction with the load board 109 and/or the DUT 106.

The circuit board 209 provides a portion of the probe holes of the test interconnect assembly 303. A probe hole can be provided using a hollow conductive via that is shaped to accommodate a portion of a compressible probe 215. Conductive vias through the circuit board 209 concentric to the grid array of the DUT 106 can be selectively connected to the conductive layers of the circuit board 209. However, in some examples, the via is not connected to any conductive layers. For example, in the shown configuration, the via for the compressible probe 215b is not connected to any conductive layer because there is no circuit board 209 layer corresponding to the signal that passes through the compressible probe 215b.

A portion of the probe hole for the compressible probe 215a is provided using a hollow via 251. The hollow via 251a can be plated or otherwise include a conductive material. The hollow via 251a provides a conductive connection to one or more supply voltage layers 245 of the circuit board 209. The connection to the supply voltage layers 245 of the circuit board 209 can enable heat dissipation and additional supply voltage conductive paths in addition to the compressible probe 215a. Relative to previous technologies, this can improve power integrity, reduce current fluctuations, and improve heat dissipation.

A portion of the probe hole for the compressible probe 215b is provided using a hollow via 251b of the circuit board 209. The hollow via 251b can be plated or otherwise include a conductive material that extends through the circuit board 209, or the hollow via 254 can refer to a hole drilled through the circuit board 209. A probe spacer 261a holds the compressible probe 215b concentric with the probe hole and the signal contact 221. The probe spacer 261a can include a shape, size, and dielectric material that is selected to provide a desired impedance that maximizes signal transmission through the compressible probe 215b.

A portion of the probe hole for the compressible probe 215c is provided using a hollow via 251c. The hollow via 251c can be plated or otherwise include a conductive material that extends through the circuit board 209. The hollow via 251c provides a conductive connection to one or more ground layers 242 of the circuit board 209. The connection to the ground layers 242 of the circuit board 209 can enable heat dissipation and additional conductive paths in addition to the compressible probe 215c. Relative to previous technologies, this can improve power integrity, reduce current fluctuations, and improve heat dissipation.

The circuit board 209 retains a distal portion of the compressible probes 215 and measurement compressible probes 216. In some examples, the circuit board 209 can be too flexible to effectively hold the compressible probes 215. The stiffening plate 212 provides rigidity to hold the circuit board 209 solidly in place against the pressure exerted by the compressible robes 215. However, in other cases the circuit board 209 includes a rigid material and/or includes sufficient layers to prevent flexion based on the pressure exerted by the compressible robes 215. Where the circuit board 209 can prevent flexion based on the pressure exerted by the compressible robes 215, the stiffening plate 212 can be omitted. The circuit board 209 the stiffening plate 212, and/or a floating plate (not shown) can provide a DUT interface of the test interconnect assembly 303. The stiffening plate 212 can include a grid array alignment aid for the grid array of the DUT 106. For example, the stiffening plate 212 can include indents that can receive solder balls, pins, and other contacts of the DUT 106. The stiffening plate 212 can additionally or alternatively include one or more raised elements that make contact with a periphery of the DUT 106. In some examples, the stiffening plate 212 does not include a grid alignment aid, and a floating plate can provide a suspended grid alignment aid between the stiffening plate 212 and the DUT 106. The floating plate can include indents that can receive solder balls, pins, and other contacts to interface with the DUT 106. The floating plate can be suspended using springs or another compressible suspension device that can enable even contact between the contacts of the DUT 106 and the compressible probes 215. In examples where the stiffening plate 212 is omitted a floating plate can provide a compressible-suspended grid alignment aid between the circuit board 209 and the DUT 106.

A distal portion of each of the compressible probes 215 and measurement compressible probes 216 can be aligned concentric with the grid array of the DUT 106. A proximal portion of each of the compressible probes can be aligned concentric with the grid array of the load board 109. The compressible probe 215a can connect the supply voltage contact 218 of the DUT 106 to the supply voltage contact 227 of the load board 109. The compressible probe 215a can provide additional conductive paths and heat dissipation by connecting to the supply voltage layer 245 of the circuit board 209. This circuit connection can be referred to as a supply voltage net. The compressible probe 215b can connect the signal contact 221 of the DUT 106 to the signal contact 230 of the load board 109. This circuit connection can be referred to as a signal net. The compressible probe 215c can connect the ground contact 224 of the DUT 106 to the ground contact 233 of the load board 109. The compressible probe 215c can provide additional conductive paths and heat dissipation by connecting to the ground layer 242 of the circuit board 209. This circuit connection can be referred to as a ground net.

The test system 300 can perform a test of the DUT 106 once the test interconnect assembly 303 is deployed to provide interconnects between the DUT 106 and the load board 109. The test system 300 applies supply voltage(s) and performs test pattern(s) using the load board 109. The supply voltage(s) and test patterns can pass through all or a subset of the compressible probes 215a, 215b, 215c. Performing test patterns can include inputting analog and/or digital voltage signals to one or more signal nets, reading analog and/or digital voltage signals from the one or more signal nets, and so on. The test system 300 can take power measurements including, without limitation, current measurements, voltage measurements, and other measurements using the compressible probe 216. In some examples, the test system 300 can take temperature measurements using the compressible probe 216 or a temperature sensor device (not shown). The test system 300 can perform a management action such as a power management action or a loopback management action based on the power measurements and temperature measurements. The power management action can include, without limitation, modifying a voltage output, modifying a current output, and disconnecting a power connection.

In the example of FIG. 3, the measurement compressible probes 216 can include measurement compressible probe 216a and measurement compressible probe 216b. The measurement compressible probe 216a can connect the supply voltage measurement contact 257a of the circuit board 209 to the supply voltage measurement contact 236a of the load board 109. The measurement compressible probe 216a can include a high-bandwidth “Kelvin” type measurement probe. The Kelvin type of probe connection can effectively eliminate current path impedance and temperature effects, thereby enabling more accurate measurement of supply voltage as experienced near the DUT, as compared to measurements through the other compressible probes 215a, 215b, 215c. The Kelvin type of connection enables the tester to better measure and control the voltage close to the DUT 106, because the Kelvin type measurement probe can bypass all or a portion of the temperature, resistance, capacitance, and inductance that can affect compressible probes 215a, 215b, 215c. The supply voltage measurement contact 236a can connect to the supply voltage layer 245 of the circuit board 209 using the via 254a. Some of the conductive layers of the circuit board 209 can extend outside the device footprint of the DUT 106. In some examples, measurement components such as the measurement compressible probe 216a, the supply voltage measurement contact 257a, and the via 254a are located outside the device footprint of the DUT 106. Locating these components outside the device footprint can help provide space and isolation for the Kelvin type of connection to a tester. A probe spacer 261b holds the measurement compressible probe 216a concentric with the probe hole and the via 254a. The probe spacer 261b can include a shape, size, and/or dielectric material that is selected to provide a desired impedance.

However, measurement components can also be located within the device footprint. For example, measurement components such as the compressible probe 216b, the supply voltage measurement contact 257b, and the via 254b are located inside the device footprint of the DUT 106 and outside of the grid array footprint. The measurement compressible probe 216b can connect the supply voltage measurement contact 257b of the circuit board 209 to the supply voltage measurement contact 236b of the load board 109. The measurement compressible probe 216b can include a high-bandwidth “Kelvin” type measurement probe. The supply voltage measurement contact 236b can connect to the supply voltage layer 245 of the circuit board 209 using the via 254b. Some of the conductive layers of the circuit board 209 can extend outside the device footprint of the DUT 106. Locating these components outside the grid array footprint can help provide space and isolation for the Kelvin type of connection to a tester, even with dense grid arrays. Locating the measurement compressible probe 216b inside the device footprint enables closer measurement of supply voltage and/or current closer to the current paths to the grid array of the DUT 106. A probe spacer 261c holds the measurement compressible probe 216b concentric with the probe hole and the via 254b. The probe spacer 261c can include a shape, size, and/or dielectric material that is selected to provide a desired impedance.

The test system 300 can perform a test of the DUT 106 once the test interconnect assembly 303 is deployed to provide interconnects between the DUT 106 and the load board 109. The test system 300 applies supply voltage(s) and performs test pattern(s) using the load board 109. The supply voltage(s) and test patterns can pass through all or a subset of the compressible probes 215a, 215b, 215c. Performing test patterns can include inputting analog and/or digital voltage signals to one or more signal nets, reading analog and/or digital voltage signals from the one or more signal nets, and so on. The test system 300 can take power measurements including, without limitation, current measurements, voltage measurements, and other measurements using the measurement compressible probe 216. In some examples, the test system 300 can take temperature measurements using the compressible probe 216 or a temperature sensor device (not shown). The test system 300 can perform a management action such as a power management action or a loopback management action based on the power measurements and temperature measurements. The power management action can include, without limitation, modifying a voltage output, modifying a current output, and disconnecting a power connection.

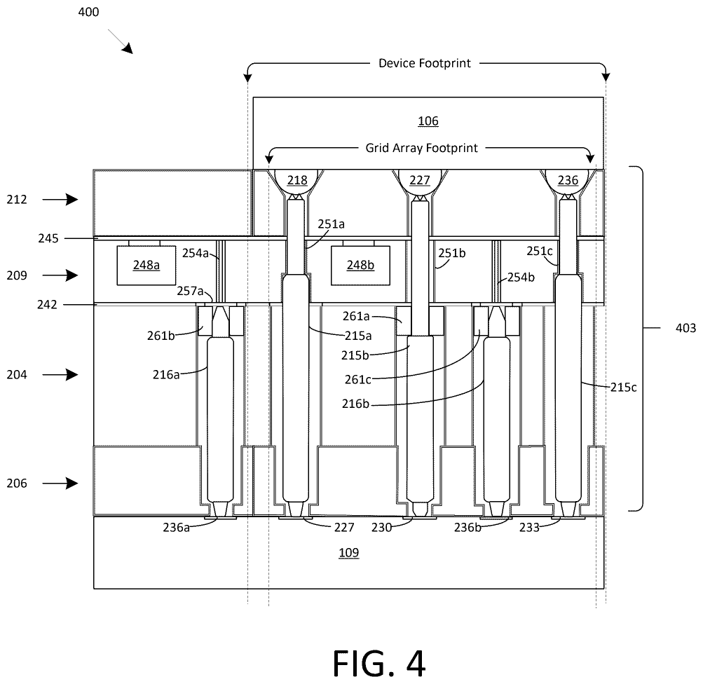

FIG. 4 is a cross-sectional view of a test system 400, according to various embodiments. Test system 400 is an example of a test system 100. The test system 400 shown in FIG. 4 includes, without limitation, a test interconnect assembly 403, a DUT 106, and a load board 109. The test interconnect assembly 103 includes, without limitation, a main housing structure 204, a cover plate 206, a circuit board 209, a stiffening plate 212, one or more compressible probes 215a, 215b, and 215c (collectively, “compressible probes 215”), and one or more measurement compressible probes 216a and 216b (collectively, “measurement compressible probes 216”). The test interconnect assembly 103 can include any number of compressible probes 215, and any number of measurement compressible probes 216. The DUT 106 includes, without limitation, a supply voltage contact 218, a signal contact 221, a ground contact 224, and other components. The load board 109 includes, without limitation, a supply voltage contact 227, a signal contact 230, a ground contact 233, one or more supply voltage measurement contacts 236a and 236b (collectively, “supply voltage measurement contacts 236”), and other components. The circuit board 209 includes, without limitation, one or more ground layers 242, one or more supply voltage layers 245, one or more capacitors 248, one or more hollow vias 251a, 251b, and 251c (collectively, “hollow vias 251”), one or more vias 254a and 254b (collectively vias 254), and one or more supply voltage measurement contacts 257a and 257b (collectively, “supply voltage measurement contacts 257”). The test interconnect assembly 103 can also include one or more probe spacers 261a, 261b, 261c (collectively, “probe spacers 261”).

The DUT 106 includes a number of contacts arranged in a grid array. A grid array includes a pattern of any kind of contacts. For example, a grid array can include a ball grid array of solder ball contacts, a land grid array of contact pads, a pin grid array of pin contacts, and so on. The contacts of the DUT 106 can be referred to as DUT contacts. The grid array of the DUT 106 can be referred to as a DUT grid array. The DUT contacts are shown as solder ball contacts. The DUT contacts include, without limitation, a supply voltage contact 218, a signal contact 221, and a ground contact 224. And although only three contacts are shown, the DUT 106 can include any number of supply voltage contacts 218, any number of signal contacts 221, and any number of ground contacts 224. Some DUTs 106 can include one or more negative voltage contacts.

The load board 109 includes a number of contacts arranged in a grid array or contact array. The grid array of the load board 109 can be referred to as a load board grid array. The load board contacts are shown as contact pads. The load board contacts include, without limitation, a supply voltage contact 227, a signal contact 230, a ground contact 233, and a supply voltage measurement contact 236. The load board 109 can include any number of supply voltage contacts 227, any number of signal contacts 230, any number of ground contacts 233, and any number of supply voltage measurement contacts 236. Some load boards 109 include one or more negative voltage contacts (not shown).

The main housing structure 204 holds or houses the compressible probes 215. To this end, the test interconnect assembly 103 includes probe holes or cavities that extend through the main housing structure 204, the cover plate 206, the circuit board 209, and the stiffening plate 212. The probe holes and/or other components of the test interconnect assembly 103 can hold the compressible probes 215 in any desired orientation. In some examples, the probe holes (and probe spacers) of the main housing structure 204 are sized and shaped to create a coaxial transmission path with a desired impedance to maximize signal transmission. The main housing structure 204 can be anodized, and the desired impedance can be achieved based on anodization parameters.

The main housing structure 204 can be constructed of a dielectric material. In other examples, the main housing structure 204 can be constructed of a conductive material. In examples where the main housing structure 204 is constructed of a conductive material, the main housing structure 204 can be grounded by a connection to a compressible probe such as the compressible probe 215c. The main housing structure 204 can be anodized to prevent shorting other compressible probes 215. The compressible probe 215c connects between the ground contact 233 of the load board 109 and the ground contact 224 of the DUT 106. The compressible probe 215c can connect the main housing structure 204 to a ground net of an overall circuit that includes the DUT 106, the load board 109, and the test interconnect assembly 103. The compressible probe 215c can connect the main housing structure 204 to a ground net using a physical connection of the compressible probe 215c to a ground plane or ground layer 242 of the circuit board 209. The ground layer 242 of the circuit board 209 can make contact with the main housing structure 204. In other examples, a probe hole of the main housing structure 204 can be sized to make direct contact with the compressible probe 215c, or a conductive spacer that fits around the compressible probe 215c can connect the compressible probe 215c to the main housing structure 204. The grounding of the main housing structure 204 can create a coaxial structure in combination with the various compressible probes 215. The compressible probe 215b carries a signal between the load board 109 and the DUT 106. Each of the compressible probes 215a and 215b, and the measurement compressible probe 216 can be surrounded by an air gap and other dielectric materials. The dielectric materials can include the anodization of the main housing structure 204. The air gap and other dielectric materials can provide a desired impedance to maximize signal transmission. The air gap and other dielectric materials can be surrounded by a ground provided using the grounded main housing structure 204. The anodization of the main housing structure 204 provides at least a portion of the desired impedance based on anodization parameters.

In examples where the main housing structure 204 is constructed of a dielectric material, the probe holes can have a conductive sheath or coating that forms a coaxial structure. In some cases, the main housing structure 204 main housing structure 204 is constructed as a single integrated unit with the circuit board 209. The conductive sheath or coating can be grounded by making contact with a ground layer 242 of the circuit board 209. For example, the compressible probe 215b can carry a signal between the load board 109 and the DUT 106. Each of the compressible probes 215a and 215b, and the measurement compressible probe 216 can be surrounded by an air gap and other dielectric materials. The dielectric materials can include anodization over a conductive portion of the sheath or coating. The air gap and other dielectric materials can provide a desired impedance to maximize signal transmission. The air gap and other dielectric materials can be surrounded by a ground provided using the grounded conductive sheath or coating. The anodization of the sheath or coating provides at least a portion of the desired impedance based on anodization parameters.

The cover plate 206 interfaces with the load board 109. The cover plate 206 retains a proximal portion of the compressible probes 215. As a result, the cover plate 206 can be referred to as a compressible probe retention plate or a load board interface of the test interconnect assembly 103. The cover plate 206 can be constructed of a dielectric material. In other examples, the cover plate 206 is constructed of a conductive material. In examples where the cover plate 206 is constructed of a conductive material, the cover plate 206 can be grounded by a connection to a compressible probe such as the compressible probe 215c. The proximal cover plate 206 can be anodized to prevent shorting other compressible probes 215. The compressible probe 215c connects the cover plate 206 to a ground net using a physical connection of the compressible probe 215c to a ground plane or ground layer 242 of the circuit board 209. A probe hole of the cover plate 206 can be sized to make direct contact with the compressible probe 215c, or a conductive spacer that fits around the compressible probe 215c can connect the compressible probe 215c to the cover plate 206. In examples where both the main housing structure 204 and the cover plate 206 are conductive, the main housing structure 204 can be grounded, and the cover plate 206 can be grounded by making contact with the main housing structure 204. The grounding of the cover plate 206 can create a coaxial structure in combination with the various compressible probes 215.

The cover plate 206 can provide a portion of the probe holes. The portion of the probe holes provided using the cover plate 206 can be sized and shaped to create a coaxial transmission path with a desired impedance to maximize signal transmission. The cover plate 206 can be anodized, and a desired impedance can be achieved based on anodization parameters.

The circuit board 209 can include a printed circuit board or another type of circuit board. The circuit board 209 can be composed using fiberglass, ceramics, polyimide or another material. The circuit board 209 can have a composite construction that includes, without limitation, one or more dielectric material and one or more conductive layers or planes. Each conductive layer includes one or more conductive traces or areas. The circuit board 209 can include any number of ground layers 242. The circuit board 209 can include any number of supply voltage layers 245. The circuit board 209 can include any number of capacitors 248. The circuit board 209 can include any number of hollow vias 251.

In the example of FIG. 4, the capacitors 248 include capacitor 248a and capacitor 248b. The capacitor 248a is located outside the device footprint. The capacitor 248b is located inside of the grid array footprint. Locating the capacitor 248b inside the grid array footprint increases the overall number (and density) of capacitors 248 of the circuit board 209. The increased number and density of capacitors 248 can increase power integrity in the area inside the grid array footprint. The capacitors 248 are shown to be embedded within a surface of the circuit board 209. The material can be etched, cut out, or otherwise removed in the area where a capacitor 248 is to be embedded. The circuit board 209 can include cutouts or etched areas in an upper layer closer to the DUT 106 and cutouts or etched areas in a lower layer closer to the main housing structure 204. The cutouts or etched areas can accommodate the capacitors 248. However, in some cases a capacitor 248 can be attached to a surface of a circuit board 209. In that case, the stiffening plate 212 can include a cutout for the capacitor 248, or the stiffening plate 212 can be absent. The capacitors 248 can be used to stabilize supply voltage levels supplied using the supply voltage layer 245 and traces. The capacitors 248 can also be used to perform circuit functions in conjunction with the load board 109 and/or the DUT 106.

The circuit board 209 provides a portion of the probe holes of the test interconnect assembly 103. A probe hole can be provided using a hollow conductive via that is shaped to accommodate a portion of a compressible probe 215. Conductive vias through the circuit board 209 concentric to the grid array of the DUT 106 can be selectively connected to the conductive layers of the circuit board 209. However, in some examples, the via is not connected to any conductive layers. For example, in the shown configuration, the via for the compressible probe 215b is not connected to any conductive layer because there is no circuit board 209 layer corresponding to the signal that passes through the compressible probe 215b.

A portion of the probe hole for the compressible probe 215a is provided using a hollow via 251. The hollow via 251a can be plated or otherwise include a conductive material. The hollow via 251a provides a conductive connection to one or more supply voltage layers 245 of the circuit board 209. The connection to the supply voltage layers 245 of the circuit board 209 can enable heat dissipation and additional supply voltage conductive paths in addition to the compressible probe 215a. Relative to previous technologies, this can improve power integrity, reduce current fluctuations, and improve heat dissipation.

A portion of the probe hole for the compressible probe 215b is provided using a hollow via 251b of the circuit board 209. The hollow via 251b can be plated or otherwise include a conductive material that extends through the circuit board 209, or the hollow via 254 can refer to a hole drilled through the circuit board 209. A probe spacer 261a holds the compressible probe 215b concentric with the probe hole and the signal contact 221. The probe spacer 261a can connect to one or more ground layers 242 of the circuit board 209. The probe spacer 261a can include a shape, size, and material that is selected to provide a desired impedance that maximizes signal transmission through the compressible probe 215b.

A portion of the probe hole for the compressible probe 215c is provided using a hollow via 251c. The hollow via 251c can be plated or otherwise include a conductive material that extends through the circuit board 209. The hollow via 251c provides a conductive connection to one or more ground layers 242 of the circuit board 209. The connection to the ground layers 242 of the circuit board 209 can enable heat dissipation and additional conductive paths in addition to the compressible probe 215c. Relative to previous technologies, this can improve power integrity, reduce current fluctuations, and improve heat dissipation.

The circuit board 209 retains a distal portion of the compressible probes 215 and measurement compressible probes 216. In some examples, the circuit board 209 can be too flexible to effectively hold the compressible probes 215. The stiffening plate 212 provides rigidity to hold the circuit board 209 solidly in place against the pressure exerted by the compressible robes 215. However, in other cases the circuit board 209 includes a rigid material and/or includes sufficient layers to prevent flexion based on the pressure exerted by the compressible robes 215. Where the circuit board 209 can prevent flexion based on the pressure exerted by the compressible robes 215, the stiffening plate 212 can be omitted. The circuit board 209 the stiffening plate 212, and/or a floating plate (not shown) can provide a DUT interface of the test interconnect assembly 103. The stiffening plate 212 can include a grid array alignment aid for the grid array of the DUT 106. For example, the stiffening plate 212 can include indents that can receive solder balls, pins, and other contacts of the DUT 106. The stiffening plate 212 can additionally or alternatively include one or more raised elements that make contact with a periphery of the DUT 106. In some examples, the stiffening plate 212 does not include a grid alignment aid, and a floating plate can provide a suspended grid alignment aid between the stiffening plate 212 and the DUT 106. The floating plate can include indents that can receive solder balls, pins, and other contacts to interface with the DUT 106. The floating plate can be suspended using springs or another compressible suspension device that can enable even contact between the contacts of the DUT 106 and the compressible probes 215. In examples where the stiffening plate 212 is omitted a floating plate can provide a compressible-suspended grid alignment aid between the circuit board 209 and the DUT 106.

A distal portion of each of the compressible probes 215 and measurement compressible probes 216 can be aligned concentric with the grid array of the DUT 106. A proximal portion of each of the compressible probes can be aligned concentric with the grid array of the load board 109. The compressible probe 215a can connect the supply voltage contact 218 of the DUT 106 to the supply voltage contact 227 of the load board 109. The compressible probe 215a can provide additional conductive paths and heat dissipation by connecting to the supply voltage layer 245 of the circuit board 209.

This circuit connection can be referred to as a supply voltage net. The compressible probe 215b can connect the signal contact 221 of the DUT 106 to the signal contact 230 of the load board 109. This circuit connection can be referred to as a signal net. The compressible probe 215c can connect the ground contact 224 of the DUT 106 to the ground contact 233 of the load board 109. The compressible probe 215c can provide additional conductive paths and heat dissipation by connecting to the ground layer 242 of the circuit board 209. This circuit connection can be referred to as a ground net.

The test system 400 can perform a test of the DUT 106 once the test interconnect assembly 103 is deployed to provide interconnects between the DUT 106 and the load board 109. The test system 400 applies supply voltage(s) and performs test pattern(s) using the load board 109. The supply voltage(s) and test patterns can pass through all or a subset of the compressible probes 215a, 215b, 215c. Performing test patterns can include inputting analog and/or digital voltage signals to one or more signal nets, reading analog and/or digital voltage signals from the one or more signal nets, and so on. The test system 400 can take power measurements including, without limitation, current measurements, voltage measurements, and other measurements using the compressible probe 216. In some examples, the test system 400 can take temperature measurements using the compressible probe 216 or a temperature sensor device (not shown). The test system 400 can perform a management action such as a power management action or a loopback management action based on the power measurements and temperature measurements. The power management action can include, without limitation, modifying a voltage output, modifying a current output, and disconnecting a power connection.

In the example of FIG. 4, the measurement compressible probes 216 can include measurement compressible probe 216a and measurement compressible probe 216b. The measurement compressible probe 216a can connect the supply voltage measurement contact 257a of the circuit board 209 to the supply voltage measurement contact 236a of the load board 109. The measurement compressible probe 216a can include a high-bandwidth “Kelvin” type measurement probe. The Kelvin type of connection enables the tester to better measure and control the voltage close to the DUT 106, because the Kelvin type measurement probe can bypass all or a portion of the temperature, resistance, capacitance, and inductance that can affect compressible probes 215a, 215b, 215c. The supply voltage measurement contact 236a can connect to the supply voltage layer 245 of the circuit board 209 using the via 254a. Some of the conductive layers of the circuit board 209 can extend outside the device footprint of the DUT 106. In some examples, measurement components such as the measurement compressible probe 216a, the supply voltage measurement contact 257a, and the via 254a are located outside the device footprint of the DUT 106. Locating these components outside the device footprint can help provide space and isolation for the Kelvin type of connection to a tester. A probe spacer 261a holds the measurement compressible probe 216a concentric with the probe hole and the via 254a. The probe spacer 261b can include a shape, size, and/or dielectric material that is selected to provide a desired impedance.

However, measurement components can also be located within the device footprint and the grid array footprint. For example, measurement components such as the compressible probe 216b, the supply voltage measurement contact 257b, and the via 254b are located inside the device footprint of the DUT 106 and outside of the grid array footprint. The measurement compressible probe 216b can connect the supply voltage measurement contact 257b of the circuit board 209 to the supply voltage measurement contact 236b of the load board 109. The measurement compressible probe 216b can include a high-bandwidth “Kelvin” type measurement probe. The supply voltage measurement contact 236b can connect to the supply voltage layer 245 of the circuit board 209 using the via 254b. Some of the conductive layers of the circuit board 209 can extend outside the device footprint of the DUT 106. Locating the measurement compressible probe 216b inside the grid array footprint enables closer measurement of supply voltage and/or current closer to the current paths to the grid array of the DUT 106. A probe spacer 261c holds the measurement compressible probe 216b concentric with the probe hole and the via 254b. The probe spacer 261c can include a shape, size, and/or dielectric material that is selected to provide a desired impedance.

The test system 400 can perform a test of the DUT 106 once the test interconnect assembly 103 is deployed to provide interconnects between the DUT 106 and the load board 109. The test system 400 applies supply voltage(s) and performs test pattern(s) using the load board 109. The supply voltage(s) and test patterns can pass through all or a subset of the compressible probes 215a, 215b, 215c. Performing test patterns can include inputting analog and/or digital voltage signals to one or more signal nets, reading analog and/or digital voltage signals from the one or more signal nets, and so on. The test system 400 can take power measurements including, without limitation, current measurements, voltage measurements, and other measurements using the measurement compressible probe 216. In some examples, the test system 100 can take temperature measurements using the compressible probe 216 or a temperature sensor device (not shown). The test system 400 can perform a management action such as a power management action or a loopback management action based on the power measurements and temperature measurements. The power management action can include, without limitation, modifying a voltage output, modifying a current output, and disconnecting a power connection.

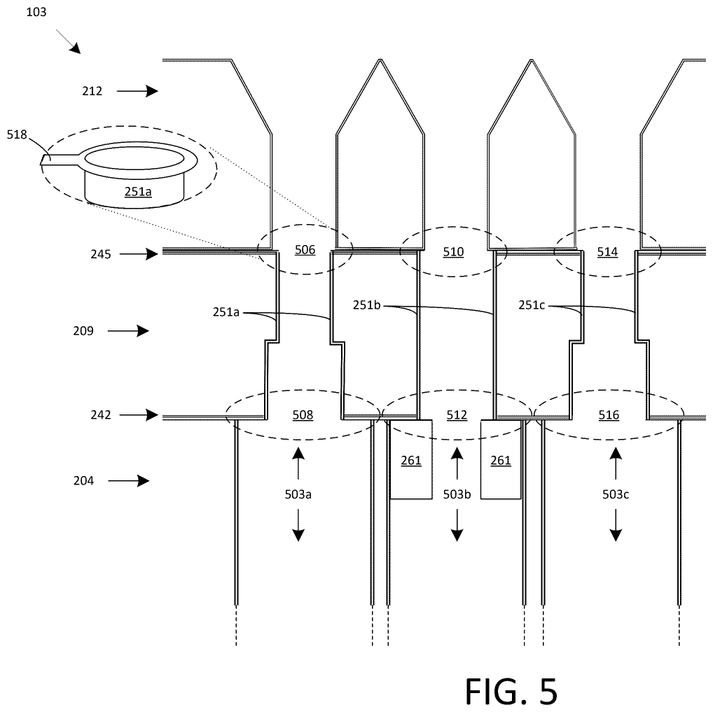

FIG. 5 is a detail view of a portion of a test interconnect assembly 103, according to various embodiments. The test interconnect assembly 103 corresponds to any of the test interconnect assemblies 203, 303, 403, 803, 903, 1003, 1103. In the shown embodiment, the test interconnect assembly 103 includes, without limitation, a main housing structure 204, a circuit board 209, a stiffening plate 212, one or more compressible probe holes 503 to contain one or more compressible probes 215 (not shown) and/or measurement compressible probes 216 (not shown), one or more probe spacers 261, via connection areas 506, 508, 510, 512, 514, 516, and other components discussed with respect to other figures. The circuit board 209 includes, without limitation, one or more ground layers 242, one or more supply voltage layers 245 with one or more traces or conductive paths 518, one or more hollow vias 251a, 251b, and 251c (collectively, “hollow vias 251”), and other components discussed with respect to other figures.

The test interconnect assembly 103 includes probe holes 503a, 503b, and 503c that hold the compressible probes (not shown) and/or measurement compressible probes 216 (not shown). The probe holes 503 extend through the main housing structure 204, the cover plate 206 (not shown), the circuit board 209, and the stiffening plate 212. The probe holes 503 and/or other components of the test interconnect assembly 103 can hold the compressible probes 215 in an orientation that is orthogonal to the distal (e.g., closer to the DUT 106) and proximal (e.g., closer to the load board 109) surfaces of the main housing structure 204. However, in other examples, the probe holes 503 can hold the compressible probes 215 at any predetermined angle. The angle of the probe holes 503 can be uniform, or the angle can be different for each of the probe holes 503.

The circuit board 209 can include a printed circuit board or another type of circuit board. The circuit board 209 can be composed using fiberglass, ceramics, polyimide or another material. The circuit board 209 can have a composite construction that includes, without limitation, one or more dielectric material and one or more conductive layers or planes. Each conductive layer includes one or more conductive traces or areas. The circuit board 209 can include any number of ground layers 242. The circuit board 209 can include any number of supply voltage layers 245.

The via connection area 506 can refer to the area of the circuit board 209 that encircles or surrounds the probe hole 503a in the supply voltage layer 245. A portion of the probe hole 503a is provided using a hollow via 251a. The hollow via 251a can be plated or otherwise include a conductive material. In this example, the hollow via 251a provides a connection to the supply voltage layer 245 of the circuit board 209. The supply voltage layer 245 can include, in the via connection area 506, one or more supply voltage traces and/or connections that connect to the hollow via 251a. The connection to the supply voltage layers 245 of the circuit board 209 can enable heat dissipation and additional supply voltage conductive paths. The hollow via 251a can be sized and shaped to receive and make contact with a corresponding compressible probe 215 (not shown) that connects to a supply voltage net. The zoomed in isometric view of the via connection area 506 shows a conductive path 518 that makes contact with and encircles the hollow via 251a. In other embodiments, multiple conductive paths 518, and/or a solid conductive plane of the ground layer 242 makes contact with the hollow via 251a and extends in all directions therefrom.

The via connection area 508 can refer to the area of the circuit board 209 that encircles or surrounds the probe hole 503a in the ground layer 242. In the via connection area 508, the ground layer 242 can include an open space or dielectric area around the probe hole 503a, so that the ground layer 242 does not short to the source-voltage-connected hollow via 251a. The material and/or size of the open space or dielectric area of the ground layer 242 in the via connection area 508 can be sized and shaped to provide a desired impedance to ground.

The via connection area 510 can refer to the area of the circuit board 209 that encircles or surrounds the probe hole 503b in the supply voltage layer 245. A portion of the probe hole 503a is provided using a hollow via 251b. The hollow via 251b can be plated or otherwise include a conductive material. In this example the hollow via 251b corresponds to a compressible probe 215 (not shown) that provides a signal path. The supply voltage layer 245 can include, in the via connection area 510, an open space or dielectric area around the probe hole 503b. As a result, the hollow via 251b does not connect to the supply voltage layer 245 of the circuit board 209.

The via connection area 512 can refer to the area of the circuit board 209 that encircles or surrounds the probe hole 503b in the ground layer 242. In order to provide a coaxial transmission path, the hollow via 251b can be grounded. To this end, the ground layer 242 in the via connection area 512 can include one or more traces and/or connections that connect to the hollow via 251b. The hollow via 251b can be sized to prevent contact with a corresponding compressible probe 215 (not shown) that connects to a signal net. To this end, the probe spacer 261 can hold the compressible probe 215 (not shown) away from the edges of hollow via 251b. The material, size, and shape of the probe spacer can provide a desired impedance to maximize signal transmission.

The via connection area 514 can refer to the area of the circuit board 209 that encircles or surrounds the probe hole 503c in the supply voltage layer 245. A portion of the probe hole 503c is provided using a hollow via 251c. The hollow via 251c can be plated or otherwise include a conductive material. In this example the hollow via 251c corresponds to a compressible probe 215 (not shown) that provides a ground connection. The supply voltage layer 245 can include, in the via connection area 514, an open space or dielectric area around the probe hole 503c. As a result, the hollow via 251c does not connect to the supply voltage layer 245 of the circuit board 209.

The via connection area 516 can refer to the area of the circuit board 209 that encircles or surrounds the probe hole 503b in the ground layer 242. In order to provide a ground connection, the hollow via 251b can be grounded. To this end, the ground layer 242 in the via connection area 516 can include one or more traces and/or connections that connect to the hollow via 251b. The hollow via 251c can be sized and shaped to receive and make contact with a corresponding compressible probe 215 (not shown) that connects to a ground net.

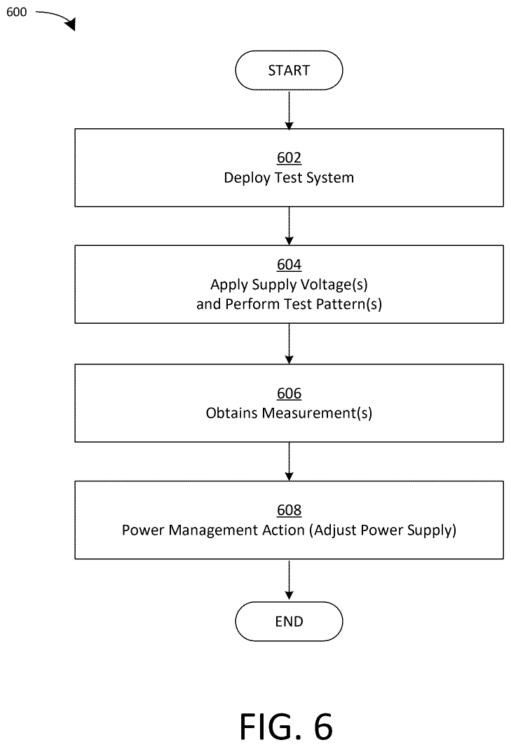

FIG. 6 is a flow diagram of method steps for power management using a test system, according to various embodiments. Although the method steps are described in conjunction with the systems of FIGS. 1-5, persons of ordinary skill in the art will understand that any system configured to perform the method steps, in any order, is within the scope of the invention.

As shown, a method 600 begins at step 602, where a test system 100 is deployed to provide interconnects between the DUT 106 and the load board 109. The test system 100 (e.g., a test system 200, 300, 400, 800, 900, 1000, and/or 1100) includes, without limitation, a test interconnect assembly 103 (e.g., a test interconnect assembly 203, 303, 403, 803, 903, 1003, and/or 1103), a DUT 106, and a load board 109. A first side of the test interconnect assembly 103 is connected to the load board 109. A second side of the test interconnect assembly 103 is connected to the DUT 106. The test interconnect assembly 103 includes a main housing structure 204, a cover plate 206, a circuit board 209, one or more compressible probes 215 and one or more measurement compressible probes 216. In some examples, the test interconnect assembly 103 includes a stiffening plate 212. Various configurations of the test interconnect assembly 103 are discussed with respect to FIGS. 1-5 and 7.

At step 604, the test system 100 applies supply voltage(s) and performs test pattern(s) using the load board 109. The load board 109 can include and/or be connected to a power supply device that provides supply voltages and test patterns. The load board 109 can include circuitry configured to apply positive and/or negative supply voltages and test patterns. The test patterns can include inputting analog and/or digital voltage signals to one or more signal nets, reading analog and/or digital voltage signals from the one or more signal nets, and so on.

At step 606, the test system 100 obtains measurements of various parameters of the test system 100. The test system 100 takes power measurements including, without limitation, current measurements, voltage measurements, and other measurements using the measurement compressible probes 216. The Kelvin-type measurement compressible probes 216 are connected to the DUT-side circuit board 209 distal from the load board 109, and provide DUT-side measurements. The test system 100 can also takes power measurements through the compressible probes 215. However, the measurements through the compressible probes 215 can cause current path impedance and temperature effects as compared to the Kelvin-type measurement compressible probes 216. As a result, the power measurements taken through the compressible probes 215 can be considered load-board-side measurements. In some examples, the test system 100 can take temperature measurements using the compressible probe 216 or a temperature sensor device.

At step 608, the test system 100 performs a management action such as a power management action or a loopback management action. The power management action can include, without limitation, modifying a voltage output, modifying a current output, and disconnecting a power connection. A power supply can be part of the load board 109, or can be separate from the load board 109. The test system 100 can include a control circuit, which can be part of the load board 109, or can be separate from the load board 109. The control circuit reads power measurements and temperature measurements taken using the measurement compressible probes 216 and/or the compressible probes 215. The control circuit identifies a management action based on various measurements including the power measurements and temperature measurements.

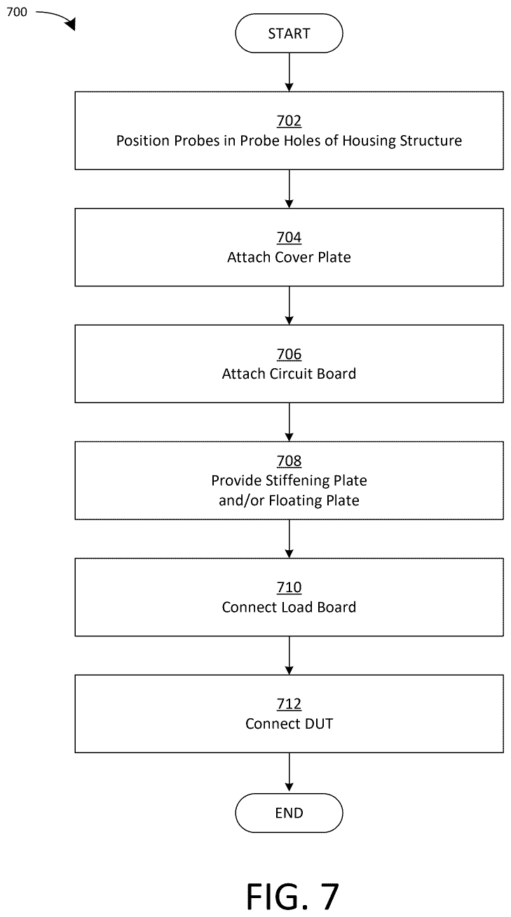

FIG. 7 is a flow diagram of method steps for configuring a test system, according to various embodiments. Although the method steps are described in conjunction with the systems of FIGS. 1-5, persons of ordinary skill in the art will understand that any system configured to perform the method steps, in any order, is within the scope of the invention.

As shown, a method 700 begins at step 702, where probes are positioned in probe holes 503 of a main housing structure 204. The main housing structure 204 can be constructed of a dielectric material and/or a conductive material. In examples where the main housing structure 204 is constructed of a conductive material, the main housing structure 204 can be grounded by a connection to a compressible probe 215 and/or a connection to circuit board 209. This grounding can enable a coaxial signal path for compressible probes 215 that carry signals and other voltages. The main housing structure 204 can be anodized to prevent shorting compressible probes 215 for signals and supply voltage.

The probe holes 503 can be at any angle relative to the DUT side and load board size of the main housing structure 204. The probes include compressible probes 215 for interconnections between a DUT 106 and a load board 109. The probes also include measurement compressible probes 216, which can include Kelvin-type probes. Positioning probes in probe holes 503 can include positioning probe spacers 261 in the probe holes 503 or onto probes prior to insertion of the probes into the probe holes 503.

At step 704, a cover plate 206 is attached to the main housing structure 204. The cover plate 206 is configured to interface with the load board 109. The cover plate 206 retains a proximal portion of the compressible probes 215, relative to the load board 109. The cover plate 206 can be constructed of a dielectric material and/or a conductive material. In examples where the cover plate 206 is constructed of a conductive material, the cover plate 206 can be grounded by a connection to a compressible probe 215 or a connection to the main housing structure 204. This grounding can enable a coaxial signal path for compressible probes 215 that carry signals and other voltages. The cover plate 206 can be anodized to prevent shorting compressible probes 215 for signals and supply voltage.

At step 706, the circuit board 209 is attached to the main housing structure 204 on a DUT-side relative to the load board 109. The circuit board 209 includes a printed circuit board or another type of circuit board 209. In some examples, the circuit board 209 is an integrated portion of the main housing structure 204. The circuit board 209 includes any number of ground layers 242 and any number of supply voltage layers 245. The circuit board 209 includes a number of hollow vias 251. The compressible probes 215 extend through the hollow vias 251. A subset of the hollow vias 251 make secure contact with a subset of the compressible probes 215, and provide connections to a ground layer 242 or a supply voltage layer 245 of the circuit board 209.

At step 708, a stiffening plate 212 is attached to the test interconnect assembly 103. The stiffening plate 212 provides rigidity to hold the circuit board 209 solidly in place against the pressure exerted by the compressible robes 215. However, in other cases the circuit board 209 includes a rigid material and/or includes sufficient layers to prevent flexion based on the pressure experienced while retaining the compressible robes 215. Where the circuit board 209 has sufficient strength and rigidity to prevent flexion based on the pressure exerted by the compressible robes 215, the stiffening plate 212 can be omitted. The circuit board 209, the stiffening plate 212, and/or a floating plate can provide a DUT interface of the test interconnect assembly 103. The stiffening plate 212 can include a grid array alignment aid for the grid array of the DUT 106. In some examples, the stiffening plate 212 does not include a grid alignment aid, and a floating plate can provide a suspended grid alignment aid between the stiffening plate 212 and the DUT 106.

At step 710, a load board 109 is connected to the test interconnect assembly 103. The load board 109 can be connected to the cover plate 206 of the test interconnect assembly 103. The test interconnect assembly 103 (e.g., test interconnect assembly 203, 303, 403, 803, 903, 1003, 1103) and the load board 109 can form a portion of the test system 100 (e.g., test system 200, 300, 400, 800, 900, 1000, 1100). The load board 109 can include and/or be connected to a power supply device that provides supply voltages and test patterns. The load board 109 can include circuitry configured to apply positive and/or negative supply voltages and test patterns. The test patterns can include inputting analog and/or digital voltage signals to one or more signal nets, reading analog and/or digital voltage signals from the one or more signal nets, and so on.

At step 712, a DUT 106 is connected to the test interconnect assembly 103. The DUT 106 is inserted or connected to a grid alignment aid of the test interconnect assembly 103. The test interconnect assembly 103 provides the grid alignment aid as part of the stiffening plate 212 or a floating plate. The contacts of the DUT 106 can connect to the compressible probes 215 of the test interconnect assembly 103. The compressible probes 215 provide paths between the contacts of the DUT 106 and corresponding contacts of the load board 109.

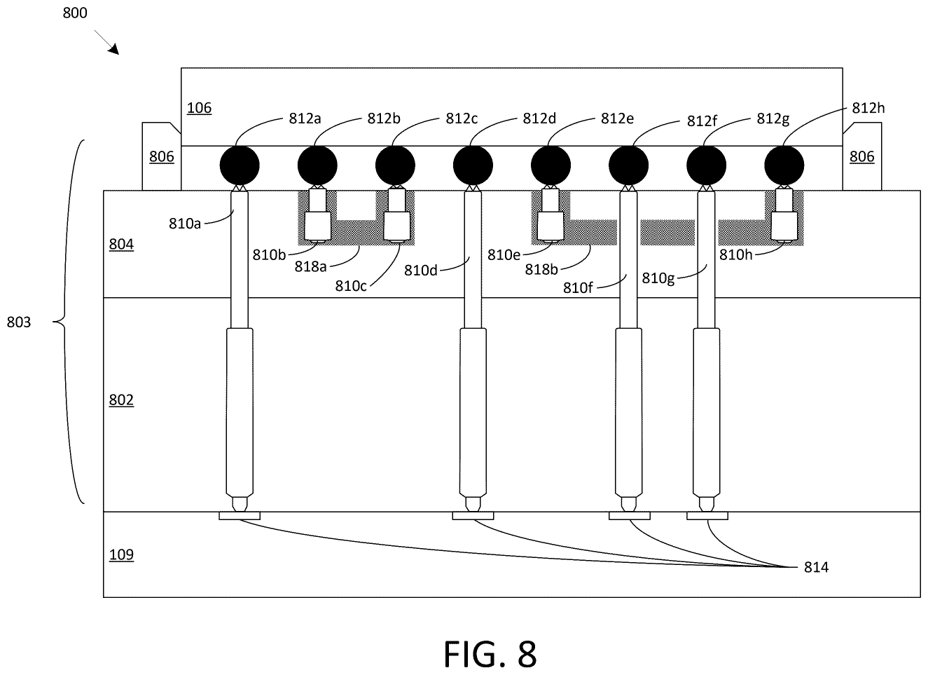

FIG. 8 is a cross-sectional view of test system 800, according to various embodiments. Test system 800 is an example of the test system 100 that includes, without limitation, a test interconnect assembly 803, a DUT 106, and a load board 109. The test interconnect assembly 803 is an example of the test interconnect assembly 103 that includes, without limitation, a main housing structure 802, a circuit board 804, one or more DUT border alignment guides 806, and one or more compressible probes 810a, 810b, 810c, 810d, 810e, 810f, 810g, 810h (compressible probes 810). The test interconnect assembly 803 can include any number of compressible probes 810 or other connectors that connect between the device under test 106 and the load board 109. The DUT 106 includes, without limitation, one or more contacts 812a, 812b, 812c, 812d, 812e, 812f, 812g, 812h (contacts 812) such as supply voltage contacts, ground contacts, loopback contacts, signal contacts, and/or the like. The load board 109 includes, without limitation, one or more contacts 814 and/or other components. The circuit board 804 includes, without limitation, one or more integrated loopbacks 818a, 818b (integrated loopbacks 818), as well as one or more hollow vias (not shown) for the compressible probes 810.

The DUT 106 includes a number of contacts 812, for example, arranged in a grid array. A grid array includes a pattern of any kind of contacts. For example, a grid array can include a ball grid array of solder ball contacts, a land grid array of contact pads, a pin grid array of pin contacts, and so on. The contacts 812 of the DUT 106 can be referred to as DUT contacts. The grid array of the DUT 106 can be referred to as a DUT grid array. In FIG. 8, the contacts 812 are shown as solder ball contacts. The DUT 106 can include any number of supply voltage contacts, any number of signal contacts, any number of loopback contacts, any number of ground contacts, any number of negative voltage contacts, and/or the like. The loopback contacts can include transmitter contacts that connect to a transmitter of the DUT 106, receiver contacts that connect to a receiver of the DUT 106, and/or transmitter/receiver contacts that connect to both a transmitter and receiver of the DUT 106.

The load board 109 includes a number of contacts 814 arranged in a grid array or contact array. The grid array of the load board 109 can be referred to as a load board grid array. In FIG. 8, the contacts 814 are shown as contact pads. The load board 109 can include any number of supply voltage contacts, any number of signal contacts, any number of ground contacts, and any number of supply voltage measurement contacts, any number of negative voltage contacts, and/or the like.

The test interconnect assembly 803 includes a circuitized component that provides integrated loopbacks 818a and 818b, as well as conductive paths that connect between the device under test 106 and the load board 109. In the example shown, the main housing structure 802 and the circuit board 804 hold or house the compressible probes 810 that provide the conductive paths. The test interconnect assembly 803 includes probe holes or cavities (not shown) that coincide with the compressible probes 810 and extend through the main housing structure 802, the circuit board 804, and other components of the test interconnect assembly 803. The conductive paths can additionally or alternatively include integrated conductive paths such as traces that extend through the circuit board 804. In some embodiments, the test interconnect assembly 803 includes or holds a Kelvin probe.

As shown, the test interconnect assembly 803 holds the compressible probes 810 in an orientation that is orthogonal to the DUT-side surface and load-board-side surface of the main housing structure 802. However, in other examples, the probe holes can hold the compressible probes 810 at a predetermined angle. The angle of the compressible probes 810 can be uniform, or the angle can be different for each of the compressible probes 810. In some examples, the probe holes (and probe spacers) of the main housing structure 802 are sized and shaped to create a coaxial transmission path with a desired impedance to maximize signal transmission. In some examples, a predetermined or desired impedance can be 50 ohms (or any other desired or configured impedance) to maximize signal transmission. The main housing structure 802 can be anodized, and the desired impedance can be achieved based on anodization parameters including, without limitation, use of a particular material, a particular thickness, and so on.

In the example shown, the main housing structure 802 provides a load board interface of the test interconnect assembly 803. For example, at least a portion of a load board side surface of the main housing structure 802 makes contact with a surface of the load board 109. The main housing structure 802 can be constructed of a dielectric material such as plastic. In other examples, the main housing structure 802 can be constructed of a conductive material such as aluminum. In examples where the main housing structure 802 is constructed of a conductive material, the main housing structure 802 can be grounded by a connection to one or more of the compressible probes 810. The main housing structure 802 can be anodized to prevent shorting other compressible probes 810. The grounding of the main housing structure 802 can create a coaxial structure in combination with the various compressible probes 810.

Where the main housing structure 802 is constructed of a dielectric material, the probe holes can have a conductive sheath or coating that forms a coaxial structure. In some cases, the main housing structure 802 is constructed as a single integrated unit with the circuit board 804. The conductive sheath or coating can be grounded by contact with a ground layer of the circuit board 84 or a ground of the load board 109 and/or a compressible probe 810. Some of the compressible probes 810 can be surrounded by an air gap and other dielectric materials. The dielectric materials can include anodization over a conductive portion of the sheath or coating. The air gap and other dielectric materials can provide a desired impedance to maximize signal transmission. The air gap and other dielectric materials can be surrounded by a ground provided using the grounded conductive sheath or coating. The anodization of the sheath or coating provides at least a portion of the desired impedance based on anodization parameters.

The housing structure 802 interfaces with the load board 109, for example, on a cover plate forming the load-board-side surface of the housing structure 802. The housing structure 802 (e.g., the cover plate or other portion thereof) retains a load-board-side portion of the compressible probes 210. As a result, a cover plate of the housing structure 802 can be referred to as a compressible probe retention plate and/or a load board interface of the test interconnect assembly 803. The load-board-side surface of the housing structure 802 or cover plate can be constructed of a dielectric material such as plastic. In other examples, the load-board-side surface of the housing structure 802 or cover plate is constructed of a conductive material such as aluminum. In examples where the load-board-side surface of the housing structure 802 or cover plate is constructed of a conductive material, a compressible probe 810 can provide a ground connection. The load-board-side surface of the housing structure 802 or cover plate can be anodized to prevent shorting other compressible probes 810.

In the example shown, the circuit board 804 provides a DUT interface of the test interconnect assembly 803. For example, at least a portion of a DUT-side surface of the circuit board 804 contacts a surface of the DUT 106. The circuit board 804 can include a printed circuit board or another type of circuit board. The circuit board 804 can be composed using fiberglass, ceramics, polyimide or another material. The circuit board 804 can have a composite construction that includes, without limitation, one or more dielectric material and one or more conductive layers or planes. Each conductive layer includes one or more conductive traces or areas. The circuit board 804 can include one or more integrated loopbacks 818 including the integrated loopback 818a and the integrated loopback 818b, one or more hollow vias for the compressible probes 810, as well as any number of ground layers and any number of supply voltage layers. In some examples, an integrated loopback 818 includes a configurable impedance and/or loss. The loss can include a resistive loss and/or reactive losses. The reactive losses can include capacitive loss and/or inductive loss. In some embodiments, the impedance and/or loss of the integrated loopback 818 is configured based on dimensions of the conductive path, materials of the conductive path, and passive components.

The integrated loopback 818a provides at least a portion of a loopback path between a first loopback contact 812b of the DUT 106 to a second loopback contact 812c of the DUT 106 that is adjacent to the first loopback contact 812b. In the example shown, the integrated loopback 218a connects to compressible probe 810b and compressible probe 810c. The compressible probe 810b provides a connection between the first loopback contact 812b and the integrated loopback 818a. The compressible probe 810c provides a connection between the second loopback contact 812c and the integrated loopback 818a. In the example shown, the compressible probes 810b and 810c do not extend to or connect to the load board 109 and/or contacts 814 of the load board 109. In some embodiments, the integrated loopback 818a connects between two (or more) points on a single side (e.g., the DUT-side) of the circuit board 804. In some embodiments, the integrated loopback 818a provides at least a portion of a recess for the compressible probe 810b and a recess for the compressible probe 810c. In some embodiments, one or more of the circuit board 804 and/or the housing structure 802 provide at least a portion of the recess for the compressible probe 810b and the recess for the compressible probe 810c. The integrated loopback 818a provides a loopback path that enables the DUT 106 to perform a self-test or a self-communication functionality such as transmitting (e.g., applying voltage and/or a signal) from the first loopback contact 812b to the second loopback contact 812c. Each of the first loopback contact 812b and the second loopback contact 812c can connect to a transmitter, a receiver, or a transmitter receiver circuit of the DUT 106. The integrated loopback 818a provides a shorter loopback path than traditional test systems that include loopback paths extending through the load board 109.

The integrated loopback 818b connects a third loopback contact 812e of the DUT 106 to a fourth loopback contact 812h of the DUT 106 that is not adjacent to the third loopback contact 812e. In the example shown, the integrated loopback 818a connects to compressible probe 810e and compressible probe 810h. The compressible probe 810e provides a connection between the third loopback contact 812e and the integrated loopback 818b. The compressible probe 810h provides a connection between the fourth loopback contact 812h and the integrated loopback 818b. In the example shown, the compressible probes 810e and 810h do not extend to or connect to the load board 109 and/or contacts 814 of the load board 109. In some embodiments, the integrated loopback 818b connects between two (or more) points on a single side (e.g., the DUT-side) of the circuit board 804. In some embodiments, the integrated loopback 818b provides at least a portion of a recess for the compressible probe 810e and a recess for the compressible probe 810h. In some embodiments, one or more of the circuit board 804 and/or the housing structure 802 provide at least a portion of the recess for the compressible probe 810e and the recess for the compressible probe 810h. The integrated loopback 818b provides a loopback path that enables the DUT 106 to perform a self-test or a self-communication functionality such as transmitting (e.g., applying voltage and/or a signal) from the third loopback contact 812e to the fourth loopback contact 812h. Each of the third loopback contact 812e and the fourth loopback contact 812h can connect to a transmitter, a receiver, or a transmitter receiver circuit of the DUT 106. The integrated loopback 818b provides a shorter loopback path than traditional test systems that include loopback paths extending through the load board 109.

In various embodiments, test interconnect assembly 803 includes one or more grid alignment aids. In the example shown, the grid alignment aids include the border alignment guides 806. The DUT border alignment guides 806 are positioned and aligned to make contact with one or more peripheral edges about a periphery of the DUT 106. The DUT border alignment guides 806 ensures that the DUT 106 edges are positioned for grid alignment. In various embodiments, the DUT border alignment guides 806 can be connected to or formed on a surface of the circuit board 804 or another component of the test interconnect assembly 803 that provides a DUT interface.

The test system 800 can perform a test of the DUT 106 once the test interconnect assembly 803 is deployed to provide interconnects between the DUT 106 and the load board 109 and the integrated loopbacks 818 for DUT self-testing. The test system 800 applies supply voltage(s) and performs test pattern(s) using the load board 109. The supply voltage(s) and test pattern(s) cause the DUT 106 to perform a self-test and/or other self-communications functionalities using the integrated loopbacks 818. The supply voltage(s) and test patterns can pass through all or a subset of the compressible probes 810 or other conductive paths between the DUT 106 and the load board 109. Performing test patterns can include inputting analog and/or digital voltage signals to one or more signal nets, reading analog and/or digital voltage signals from the one or more signal nets, and so on. In some embodiments, the test system receives, from the DUT 106 and through one or more of the of the compressible probes 810 or other conductive paths, an indication of a result of a self-test performed by the DUT 106. The test system 800 can also make power measurements including, without limitation, current measurements, voltage measurements, and other measurements. The measurements are made using one or more of the of the compressible probes 810 or other conductive paths. The test system 800 can perform a loopback/self-test management action and/or a power management action based on the various measurements and corresponding self-test results. The power management action can include, without limitation, modifying a voltage output, modifying a current output, and disconnecting a power connection. A self-test management action can include an additional test pattern, storing a self-test result in a data store, and/or the power management action.

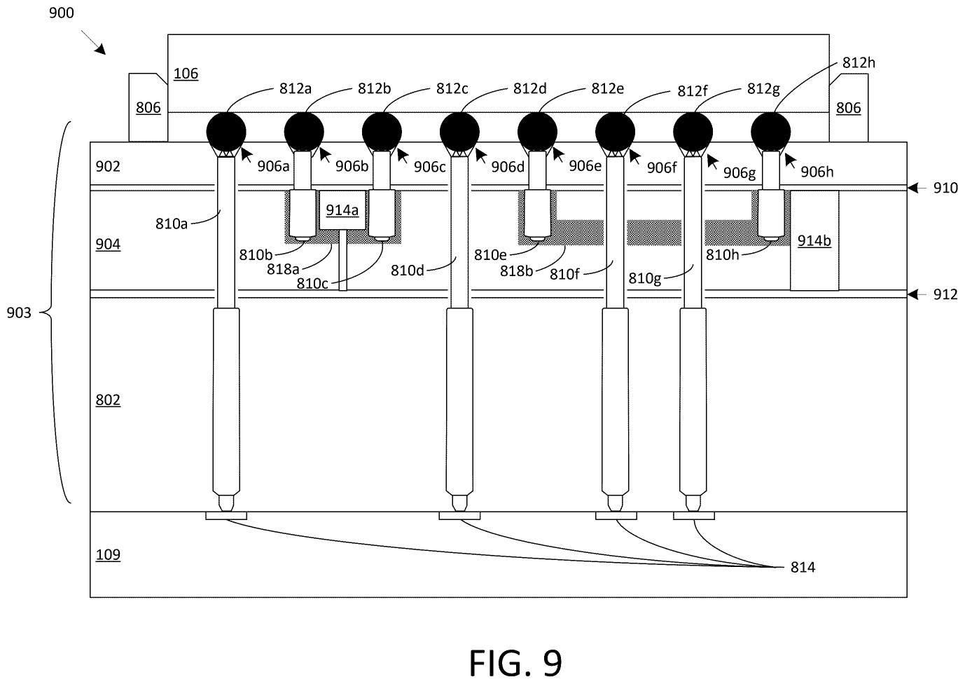

FIG. 9 is a cross-sectional view of a test system 900, according to various embodiments. Test system 900 is an example of a test system 100 that includes, without limitation, a test interconnect assembly 903, a DUT 106, and a load board 109. The test interconnect assembly 903 is an example of the test interconnect assembly 103 includes, without limitation, a main housing structure 802, a circuit board 904, a stiffening plate 902, one or more DUT border alignment guides 806, and one or more compressible probes 810a, 810b, 810c, 810d, 810e, 810f, 810g, 810h (compressible probes 810). The test interconnect assembly 903 can include any number of compressible probes 810 or other connectors that connect between the device under test 106 and the load board 109. The DUT 106 includes, without limitation, one or more contacts 812a, 812b, 812c, 812d, 812e, 812f, 812g, 812h (contacts 812) such as supply voltage contacts, ground contacts, loopback contacts, signal contacts, and/or the like. The load board 109 includes, without limitation, one or more contacts 814 and/or other components. The circuit board 904 includes, without limitation, one or more integrated loopbacks 818a, 818b (integrated loopbacks 818), as well as one or more hollow vias (not shown) for the compressible probes 810. The circuit board 904 includes, without limitation, one or more source voltage planes or traces 910, one or more ground planes or traces 912, and one or more passive circuit components 914a, 914b (passive circuit components 914). The stiffening plate 902 includes, without limitation, and one or more grid contact alignment aids 906a, 906b, 906c, 906d, 906e, 906f, 906g, 906h (grid contact alignment aids 906).

Some components of the test system 900 can be described, for example, as discussed with respect to the other example test systems 100 described above. In the example shown, the test interconnect assembly 903 additionally includes a stiffening plate 902 that provides rigidity. The stiffening plate 902 provides a DUT interface of the test interconnect assembly 903. For example, at least a portion of a DUT-side surface of the stiffening plate 902 contacts a surface of the DUT 106. The stiffening plate 902 can include a rigid material such as a rigid metallic, polymer, rubber, or other material that is more rigid than the circuit board 904. The stiffening plate 902 provides grid alignment aids including the grid contact alignment aids 906. In some examples, the stiffening plate 902 also includes or is attached to one or more DUT border alignment guides 806.

The circuit board 904 can include a printed circuit board or another type of circuit board. The circuit board 904 can be composed using fiberglass, ceramics, polyimide or another material. The circuit board 904 can have a composite construction that includes, without limitation, one or more dielectric material and one or more conductive layers or planes. Each conductive layer includes one or more conductive traces or areas. The circuit board 904 can include one or more integrated loopbacks 818 including the integrated loopback 818a and the integrated loopback 818b, one or more hollow vias for the compressible probes 810, as well as any number of ground layers and any number of supply voltage layers.

In the example shown, the circuit board 904 includes conductive planes or layers including the source voltage plane 910 and the ground plane 912. The conductive planes or layers provide nearby connections for a loopback circuit that includes an integrated loopback 818 as well as one or more of the passive circuit components 914 such as capacitors, resistors, and/or inductors. In some examples, an integrated loopback 818 includes a configurable impedance and/or loss that is configured based on one or more target or threshold values. In some embodiments, the impedance and/or loss of the integrated loopback 818 is configured based on dimensions of the conductive path, materials of the conductive path, and passive circuit components 914. In some embodiments, one or more of the passive circuit components 914 are provided to smooth current and/or voltage of the loopback circuit. In some embodiments, one or more of the passive circuit components 914 utilize a source voltage and/or a ground. As a result, using the embedded or integrated passive circuit components 914 of the circuit board 904 in association with the integrated loopbacks 818 enables shorter ground and/or voltage connections. Using integrated passive circuit components 914 reduces signal interference such as antenna effects and other parasitic effects, relative to traditional technologies. The conductive planes or layers also enable heat dissipation and additional conductive paths for source voltage and grounding. Relative to previous technologies, this improves power integrity, reduces current fluctuations, and improves heat dissipation. Additionally, the conductive planes or layers can provide connections for one or more Kelvin probes.

The integrated loopback 818a provides at least a portion of a loopback path between a first loopback contact 812b of the DUT 106 to a second loopback contact 812c of the DUT 106 that is adjacent to the first loopback contact 812b. In the example shown, the integrated loopback 818a connects to compressible probe 810b and compressible probe 810c. The compressible probe 810b provides a connection between the first loopback contact 812b and the integrated loopback 818a. The compressible probe 810c provides a connection between the second loopback contact 812c and the integrated loopback 818a. In the example shown, the compressible probes 810b and 810c do not extend to or connect to the load board 109 and/or contacts 814 of the load board 109. In some embodiments, the integrated loopback 818a connects between two (or more) points on a single side (e.g., the DUT-side) of the circuit board 904. In some embodiments, the integrated loopback 818a provides at least a portion of a recess for the compressible probe 810b and a recess for the compressible probe 810c. In some embodiments, one or more of the circuit board 904 and/or the housing structure 802 provide at least a portion of the recess for the compressible probe 810b and the recess for the compressible probe 810c. The integrated loopback 818a provides a loopback path that enables the DUT 106 to perform a self-test or a self-communication functionality such as transmitting (e.g., applying voltage and/or a signal) from the first loopback contact 812b to the second loopback contact 812c. Each of the first loopback contact 812b and the second loopback contact 812c can connect to a transmitter, a receiver, or a transmitter receiver circuit of the DUT 106. The integrated loopback 818a provides a shorter loopback path than traditional test systems that include loopback paths extending through the load board 109.

A loopback circuit includes the integrated loopback 818a and the passive circuit component 914a. The passive circuit component 914a is embedded in a surface of the circuit board 904, for example, by etching or otherwise removing a portion of the circuit board 904. The passive circuit component 914a includes, for example, a capacitor, resistor, an inductor, and/or the like. While the loopback circuit is shown to include a single passive circuit component 914a, the loopback circuit can include any number of passive circuit components 914, including zero. In some examples, the passive circuit component 914a connects to the integrated loopback 818a and one or more of the source voltage plane 910 or the ground plane 912. In the example shown, the passive circuit component 914a connects to the integrated loopback 818a and the ground plane 912. The passive circuit component 914a connects to the ground plane 912 using a trace or circuit path that can be insulated from the integrated loopback 818a, for example, to prevent grounding or shorting of the integrated loopback 818a.

The integrated loopback 818b connects a third loopback contact 812e of the DUT 106 to a fourth loopback contact 812h of the DUT 106 that is not adjacent to the third loopback contact 812e. In the example shown, the integrated loopback 818b connects to compressible probe 810e and compressible probe 810h. The compressible probe 810e provides a connection between the third loopback contact 812e and the integrated loopback 818b. The compressible probe 810h provides a connection between the fourth loopback contact 812h and the integrated loopback 818b. In the example shown, the compressible probes 810e and 810h do not extend to or connect to the load board 109 and/or contacts 814 of the load board 109. In some embodiments, the integrated loopback 818b connects between two (or more) points on a single side (e.g., the DUT-side) of the circuit board 904. In some embodiments, the integrated loopback 818b provides at least a portion of a recess for the compressible probe 810e and a recess for the compressible probe 810h. In some embodiments, one or more of the circuit board 904 and/or the housing structure 802 provide at least a portion of the recess for the compressible probe 810e and the recess for the compressible probe 810h. The integrated loopback 818b provides a loopback path that enables the DUT 106 to perform a self-test or a self-communication functionality such as transmitting (e.g., applying voltage and/or a signal) from the third loopback contact 812e to the fourth loopback contact 812h. Each of the third loopback contact 812e and the fourth loopback contact 812h can connect to a transmitter, a receiver, or a transmitter receiver circuit of the DUT 106. The integrated loopback 818b provides a shorter loopback path than traditional test systems that include loopback paths extending through the load board 109.

A loopback circuit includes the integrated loopback 818b and the passive circuit component 914b. In this example, the passive circuit component 914b is embedded or inserted into a hole, via, or opening that extends through the circuit board 904. The passive circuit component 914b includes, for example, a capacitor, resistor, an inductor, and/or the like. While the loopback circuit is shown to include a single passive circuit component 914b, the loopback circuit can include any number of passive circuit components 914. In some examples, the passive circuit component 914b connects to the integrated loopback 818b and one or more of the source voltage plane 910 or the ground plane 912. In the example shown, the passive circuit components 914 extends between the source voltage plane 910 and the ground plane 912. The passive circuit component 914b connects directly to the integrated loopback 818a and one or more of the source voltage plane 910 or the ground plane 912.

In various embodiments, test interconnect assembly 903 includes one or more grid alignment aids or components. In the example shown, the grid alignment components include the border alignment guides 806 and the grid contact alignment aids 906. The DUT border alignment guides 806 are positioned and aligned to make contact with one or more peripheral edges about a periphery of the DUT 106. The DUT border alignment guides 806 ensures that the DUT 106 edges are positioned for grid alignment. In various embodiments, the DUT border alignment guides 806 can be connected to or formed on a surface of the circuit board 904 or another component of the test interconnect assembly 903 that provides a DUT interface.

The test system 900 can perform a test of the DUT 106 once the test interconnect assembly 903 is deployed to provide interconnects between the DUT 106 and the load board 109 and the integrated loopbacks 818 for DUT self-testing. The test system 900 applies supply voltage(s) and performs test pattern(s) using the load board 109. The supply voltage(s) and test pattern(s) cause the DUT 106 to perform a self-test and/or other self-communications functionalities using the integrated loopbacks 818.

The supply voltage(s) and test patterns can pass through all or a subset of the compressible probes 810 or other conductive paths between the DUT 106 and the load board 109. Performing test patterns can include inputting analog and/or digital voltage signals to one or more signal nets, reading analog and/or digital voltage signals from the one or more signal nets, and so on. In some embodiments, the test system receives, from the DUT 106 and through one or more of the of the compressible probes 810 or other conductive paths, an indication of a result of a self-test performed by the DUT 106. The test system 900 can also make power measurements including, without limitation, current measurements, voltage measurements, and other measurements. The measurements are made using one or more of the of the compressible probes 810 or other conductive paths. The test system 900 can perform a self-test management action and/or a power management action based on the various measurements and corresponding self-test results. The power management action can include, without limitation, modifying a voltage output, modifying a current output, and disconnecting a power connection. A self-test management action can include an additional test pattern, storing a self-test result in a data store, and/or the power management action.

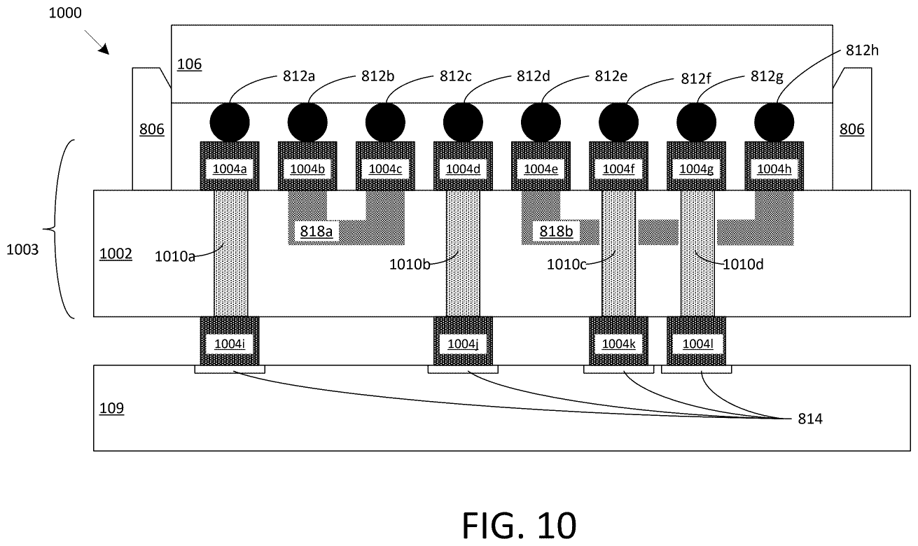

FIG. 10 is a cross-sectional view of a test system 1000, according to various embodiments. Test system 1000 is an example of the test system 100 that includes, without limitation, a test interconnect assembly 1003, a DUT 106, and a load board 109. The test interconnect assembly 1003 is an example of the test interconnect assembly 103 that includes, without limitation, a circuitized elastomer component 1002, one or more DUT border alignment guides 806, one or more interface connectors 1004 including one or more DUT interface connectors 1004a, 1004b, 1004c, 1004d, 1004e, 1004f, 1004g, 1004h (DUT interface connectors 1004), and one or more load board interface connectors 1004i, 1004j, 1004k, 1004| (load board interface connectors 1004). The DUT 106 includes, without limitation, one or more contacts 812a, 812b, 8120, 812d, 812e, 812f, 812g, 812h (contacts 812) such as supply voltage contacts, ground contacts, loopback contacts, signal contacts, and/or the like. The load board 109 includes, without limitation, one or more contacts 814 and/or other components. The circuitized elastomer component 1002 includes one or more integrated loopbacks 818a, 818b (integrated loopbacks 818) as well as one or more integrated conductive paths 1010a, 1010b, 1010c, 1010d (integrated conductive paths 1010).

Some components of the test system 1000 can be described, for example, as discussed with respect to the other example test systems 100 described above. In this example, In the example shown, the circuitized elastomer component 1002 is a circuitized component that provides one or more integrated loopbacks 818a and 818b and one or more integrated conductive paths 1010. In some examples, an integrated loopback 818 includes a configurable impedance and/or loss. The integrated conductive paths 1010 connect between the device under test 106 and the load board 109, for example, by connecting to corresponding DUT interface connectors 1004 and the load board interface connectors 1004. While the integrated conductive paths 1010 are shown as straight paths that are orthogonal to the interfacing surfaces of the circuitized elastomer component 1002, the integrated conductive paths 1010 can be formed at angle and any shape for a desired connection between the device under test 106 and the load board 109. The circuitized elastomer component 1002 can include a substrate that includes an elastomer compound. The integrated conductive paths 1010 can include a conductive powder that becomes conductive when compressed. In some embodiments, integrated loopbacks 818a and 818b also include a conductive powder that becomes conductive when compressed. The conductive powder can include nickel or another ferrous and/or conductive metal and can be plated with a conductive metal such as silver or gold. In some examples, a component of a test system that holds the DUT 106 to the DUT interface provides compression that causes the conductive powder of the integrated loopbacks 818 and/or the integrated conductive paths 1010 to be conductive. In some embodiments, the integrated loopbacks 818 and/or the integrated conductive paths 1010 are elastomer circuit paths that include elastomer and the conductive powder. In some embodiments, the integrated conductive paths 1010 are metallic or other solid conductive paths. In alternative embodiments, the shown circuitized elastomer component 1002 can instead include a printed or other circuit board with conductive traces (e.g., rather than an elastomer component). The circuitized elastomer component 1002 (or circuit board) can form an interposer situated or disposed between the DUT interface connectors 1004 and the load board interface connectors 1004. Additionally, conductive planes or layers of the circuitized elastomer component 1002 can provide connections for one or more Kelvin probes. In some embodiments, an additional DUT-side circuit board (not shown) on a side of the circuitized elastomer component 1002 closer to the DUT 106 can include DUT-side connections for one or more Kelvin probes.

In some embodiments, the interface connectors 1004, including each of the DUT interface connectors 1004a-h and the load board interface connectors 1004i-I, include an elastomer compound filled with or otherwise including conductive powder that becomes conductive when compressed. As a result, when the test interconnect assembly 1003 holds the DUT 106 in place (e.g., vertically in the figure), the conductive powder of the DUT interface connectors 1004, the load board interface connectors 1004, and the integrated conductive paths 1010 becomes conductive.

In the example shown, the load board interface connectors 1004 (and the circuitized elastomer component 1002) provide a load board interface of the test interconnect assembly 1003. For example, the load board interface connectors 1004 make contact with a surface of the load board 109 and the load board side surface of the circuitized elastomer component 1002. The DUT interface connectors 1004 (and the circuitized elastomer component 1002) provide a DUT interface of the test interconnect assembly 1003. For example, the DUT interface connectors 1004 make contact with a surface of the load board 109 and the DUT side surface of the circuitized elastomer component 1002.

The integrated loopback 818a provides at least a portion of a loopback path between a first loopback contact 812b of the DUT 106 to a second loopback contact 812c of the DUT 106 that is adjacent to the first loopback contact 812b. In the example shown, the integrated loopback 818a connects to the first loopback contact 812b using DUT interface connector 1004b and connects to the second loopback contact 812c using the DUT interface connector 1004c. The DUT interface connector 1004b provides a connection between the first loopback contact 812b and the integrated loopback 818a.

The DUT interface connector 1004c provides a connection between the second loopback contact 812c and the integrated loopback 818a. In the example shown, the loopback path does not extend to or connect to the load board 109 and/or contacts 814 of the load board 109. In some embodiments, the integrated loopback 818a connects between two (or more) points on a single side (e.g., the DUT-side) of the circuitized elastomer component 1002. In some embodiments, the integrated loopback 218a (and/or the circuitized elastomer component 1002) provides at least a portion of a recess for the DUT interface connector 1004b and a recess for the DUT interface connector 1004c. The integrated loopback 818a provides a loopback path that enables the DUT 106 to perform a self-test or a self-communication functionality such as transmitting (e.g., applying voltage and/or a signal) from the first loopback contact 812b to the second loopback contact 812c. Each of the first loopback contact 812b and the second loopback contact 812c can connect to a transmitter, a receiver, or a transmitter receiver circuit of the DUT 106. The integrated loopback 818a provides a shorter loopback path than traditional test systems that include loopback paths extending through the load board 109.

The integrated loopback 818b provides at least a portion of a loopback path between a third loopback contact 812e of the DUT 106 to a fourth loopback contact 812h that is not adjacent to the third loopback contact 812e. In the example shown, the integrated loopback 818b connects to the third loopback contact 812e using DUT interface connector 1004e and connects to the fourth loopback contact 812h using the DUT interface connector 1004h. The DUT interface connector 1004e provides a connection between the third loopback contact 812e and the integrated loopback 818b. The DUT interface connector 1004h provides a connection between the fourth loopback contact 812h and the integrated loopback 818b. In the example shown, the loopback path does not extend to or connect to the load board 109 and/or contacts 814 of the load board 109. In some embodiments, the integrated loopback 818b connects between two (or more) points on a single side (e.g., the DUT-side) of the circuitized elastomer component 1002. In some embodiments, the integrated loopback 818c (and/or the circuitized elastomer component 1002) provides at least a portion of a recess for the DUT interface connector 1004e and a recess for the DUT interface connector 1004h. The integrated loopback 818b provides a loopback path that enables the DUT 106 to perform a self-test or a self-communication functionality such as transmitting (e.g., applying voltage and/or a signal) from the third loopback contact 812e to the fourth loopback contact 812h. Each of the third loopback contact 812e and the fourth loopback contact 812h can connect to a transmitter, a receiver, or a transmitter receiver circuit of the DUT 106. The integrated loopback 818b provides a shorter loopback path than traditional test systems that include loopback paths extending through the load board 109.

In various embodiments, test interconnect assembly 1003 includes one or more grid alignment aids. In the example shown, the grid alignment aids include the border alignment guides 806. The DUT border alignment guides 806 are positioned and aligned to make contact with one or more peripheral edges about a periphery of the DUT 106. The DUT border alignment guides 806 ensures that the DUT 106 edges are positioned for grid alignment. In various embodiments, the DUT border alignment guides 806 can be connected to or formed on a surface of the circuitized elastomer component 1002 or another component of the test interconnect assembly 1003 that provides a DUT interface.

The test system 1000 can perform a test of the DUT 106 once the test interconnect assembly 1003 is deployed to provide interconnects between the DUT 106 and the load board 109 and the integrated loopbacks 818 for DUT self-testing. The test system 1000 applies supply voltage(s) and performs test pattern(s) using the load board 109. The supply voltage(s) and test pattern(s) cause the DUT 106 to perform a self-test and/or other self-communications functionalities using the integrated loopbacks 818. The supply voltage(s) and test patterns can pass through all or a subset of the compressible probes 810 or other conductive paths between the DUT 106 and the load board 109. Performing test patterns can include inputting analog and/or digital voltage signals to one or more signal nets, reading analog and/or digital voltage signals from the one or more signal nets, and so on. In some embodiments, the test system receives, from the DUT 106 and through one or more of the of the compressible probes 810 or other conductive paths, an indication of a result of a self-test performed by the DUT 106. The test system 1000 can also make power measurements including, without limitation, current measurements, voltage measurements, and other measurements. The measurements are made using one or more of the of the integrated conductive paths 1010 or other conductive paths. The test system 1000 can perform a self-test management action and/or a power management action based on the various measurements and corresponding self-test results. The power management action can include, without limitation, modifying a voltage output, modifying a current output, and disconnecting a power connection. A self-test management action can include an additional test pattern, storing a self-test result in a data store, and/or the power management action.

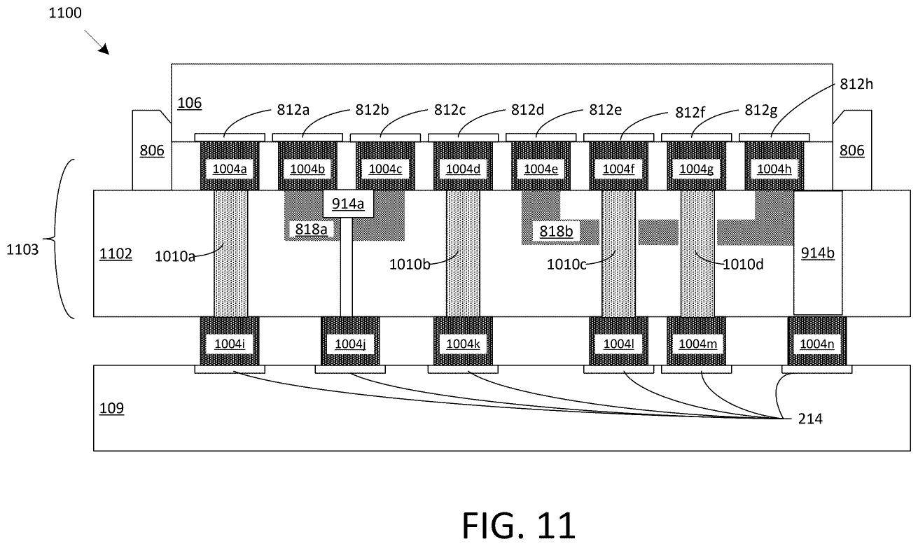

FIG. 11 is a cross-sectional view of a test system 1100, according to various embodiments. Test system 1100 is an example of the test system 100 that includes, without limitation, a test interconnect assembly 1103, a DUT 106, and a load board 109. The test interconnect assembly 1103 is an example of the test interconnect assembly 103 that includes, without limitation, a circuitized elastomer component 1102, one or more DUT border alignment guides 806, one or more interface connectors 1004 including one or more DUT interface connectors 1004a, 1004b, 1004c, 1004d, 1004e, 1004f, 1004g, 1004h (DUT interface connectors 1004), and one or more load board interface connectors 1004i, 1004j, 1004k, 1004| (load board interface connectors 1004). The DUT 106 includes, without limitation, one or more contacts 812a, 812b, 812c, 812d, 812e, 812f, 812g, 812h (contacts 812) such as supply voltage contacts, ground contacts, loopback contacts, signal contacts, and/or the like. In FIG. 11, the contacts 812 are shown as contact pads. The load board 109 includes, without limitation, one or more contacts 814 and/or other components. The circuitized elastomer component 1102 includes one or more integrated loopbacks 818a, 818b (integrated loopbacks 818) as well as one or more integrated conductive paths 1010a, 1010b, 1010c, 1010d (integrated conductive paths 1010), as well as and one or more passive circuit components 914a, 914b (passive circuit components 914).

Some components of the test system 1100 can be described, for example, as discussed with respect to the other example test systems 100 described above. In the example shown, a loopback circuit includes the integrated loopback 818a and the passive circuit component 914a. The passive circuit component 914a is embedded in a surface of the circuitized elastomer component 1102, for example, by etching or otherwise removing a portion of the circuitized elastomer component 1102. The passive circuit component 914a includes, for example, a capacitor, resistor, an inductor, and/or the like. While the loopback circuit is shown to include a single passive circuit component 914a, the loopback circuit can include any number of passive circuit components 914. In the embodiment shown, passive circuit component 914a connects to the integrated loopback 818a and a ground contact 814 of the load board 109 using load board interface connector 1004j. In the example shown, the passive circuit component 914a connects to the integrated loopback 818a and one or more of the source voltage plane or the ground plane embedded in the circuitized elastomer component 1102. The passive circuit component 914a connects to the ground plane 912 using a trace or integrated conductive path that includes conductive powder. The trace or integrated conductive path can be insulated from the integrated loopback 818a, for example, to prevent grounding or shorting of the integrated loopback 818a. In some embodiments, an integrated loopback 818 includes a configurable impedance and/or loss. Additionally, conductive planes or layers of the circuitized elastomer component 1002 can provide connections for one or more Kelvin probes. In some embodiments, an additional DUT-side circuit board (not shown) on a side of the circuitized elastomer component 1002 closer to the DUT 106 can include DUT-side connections for one or more Kelvin probes.

The integrated loopback 818a provides at least a portion of a loopback path between a first loopback contact 812b of the DUT 106 to a second loopback contact 812c of the DUT 106 that is adjacent to the first loopback contact 812b. In the example shown, the integrated loopback 818a connects to the first loopback contact 812b using DUT interface connector 1004b and connects to the second loopback contact 812c using the DUT interface connector 1004c. The DUT interface connector 1004b provides a connection between the first loopback contact 812b and the integrated loopback 818a. The DUT interface connector 1004c provides a connection between the second loopback contact 812c and the integrated loopback 818a. In the example shown, the loopback path does not extend to or connect to the load board 109 and/or contacts 814 of the load board 109. In some embodiments, the integrated loopback 818a connects between two (or more) points on a single side (e.g., the DUT-side) of the circuitized elastomer component 1102. In some embodiments, the integrated loopback 818a (and/or the circuitized elastomer component 1102) provides at least a portion of a recess for the DUT interface connector 1004b and a recess for the DUT interface connector 1004c. The integrated loopback 818a provides a loopback path that enables the DUT 106 to perform a self-test or a self-communication functionality such as transmitting (e.g., applying voltage and/or a signal) from the first loopback contact 812b to the second loopback contact 812c. Each of the first loopback contact 812b and the second loopback contact 812c can connect to a transmitter, a receiver, or a transmitter receiver circuit of the DUT 106. The integrated loopback 818a provides a shorter loopback path than traditional test systems that include loopback paths extending through the load board 109.

A loopback circuit includes the integrated loopback 818b and the passive circuit component 914b. In this example, the passive circuit component 914b is embedded or inserted into a hole, via, or opening that extends through the circuitized elastomer component 1102. The passive circuit component 914b includes, for example, a capacitor, resistor, an inductor, and/or the like. While the loopback circuit is shown to include a single passive circuit component 914b, the loopback circuit can include any number of passive circuit components 914. In some examples, the passive circuit component 914b connects to the integrated loopback 818b and one or more of a source voltage plane or a ground plane embedded in the circuitized elastomer component 1102. In the embodiment shown, passive circuit component 914b connects to the integrated loopback 818b and a ground contact 814 of the load board 109 using load board interface connector 1004n.

The integrated loopback 818b provides at least a portion of a loopback path between a third loopback contact 812e of the DUT 106 to a fourth loopback contact 812h that is adjacent to the third loopback contact 812e. In the example shown, the integrated loopback 818b connects to the third loopback contact 812e using DUT interface connector 1004e and connects to the fourth loopback contact 812h using the DUT interface connector 1004h. The DUT interface connector 1004e provides a connection between the third loopback contact 812e and the integrated loopback 818b. The DUT interface connector 1004h provides a connection between the fourth loopback contact 812h and the integrated loopback 818b. In the example shown, the loopback path does not extend to or connect to the load board 109 and/or contacts 814 of the load board 109. In some embodiments, the integrated loopback 818b connects between two (or more) points on a single side (e.g., the DUT-side) of the circuitized elastomer component 1102. In some embodiments, the integrated loopback 818c (and/or the circuitized elastomer component 1102) provides at least a portion of a recess for the DUT interface connector 1004e and a recess for the DUT interface connector 1004h. The integrated loopback 818b provides a loopback path that enables the DUT 106 to perform a self-test or a self-communication functionality such as transmitting (e.g., applying voltage and/or a signal) from the third loopback contact 812e to the fourth loopback contact 812h. Each of the third loopback contact 812e and the fourth loopback contact 812h can connect to a transmitter, a receiver, or a transmitter receiver circuit of the DUT 106. The integrated loopback 818b provides a shorter loopback path than traditional test systems that include loopback paths extending through the load board 109.

In various embodiments, test interconnect assembly 1103 includes one or more grid alignment aids. In the example shown, the grid alignment aids include the border alignment guides 806. The DUT border alignment guides 806 are positioned and aligned to make contact with one or more peripheral edges about a periphery of the DUT 106. The DUT border alignment guides 806 ensures that the DUT 106 edges are positioned for grid alignment. In various embodiments, the DUT border alignment guides 806 can be connected to or formed on a surface of the circuitized elastomer component 1102 or another component of the test interconnect assembly 1103 that provides a DUT interface.

The test system 1100 can perform a test of the DUT 106 once the test interconnect assembly 1103 is deployed to provide interconnects between the DUT 106 and the load board 109 and the integrated loopbacks 818 for DUT self-testing. The test system 1100 applies supply voltage(s) and performs test pattern(s) using the load board 109. The supply voltage(s) and test pattern(s) cause the DUT 106 to perform a self-test and/or other self-communications functionalities using the integrated loopbacks 818. The supply voltage(s) and test patterns can pass through all or a subset of the compressible probes 810 or other conductive paths between the DUT 106 and the load board 109. Performing test patterns can include inputting analog and/or digital voltage signals to one or more signal nets, reading analog and/or digital voltage signals from the one or more signal nets, and so on. In some embodiments, the test system receives, from the DUT 106 and through one or more of the of the compressible probes 810 or other conductive paths, an indication of a result of a self-test performed by the DUT 106. The test system 1100 can also make power measurements including, without limitation, current measurements, voltage measurements, and other measurements. The measurements are made using one or more of the of the integrated conductive paths 1010 or other conductive paths. The test system 1100 can perform a self-test management action and/or a power management action based on the various measurements and corresponding self-test results. The power management action can include, without limitation, modifying a voltage output, modifying a current output, and disconnecting a power connection. A self-test management action can include an additional test pattern, storing a self-test result in a data store, and/or the power management action.

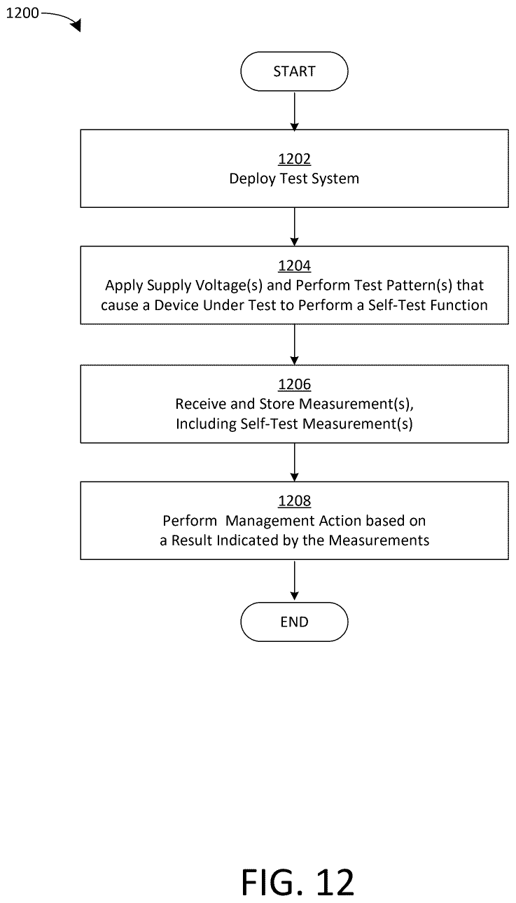

FIG. 12 is a flow diagram of method steps for self-test management using a test system, according to various embodiments. Although the method steps are described in conjunction with the embodiments of FIGS. 1-5 and 8-11, persons of ordinary skill in the art will understand that any system configured to perform the method steps, in any order, is within the scope of the invention.

As shown, a method 1200 begins at step 1202, where a test system 100 (e.g., a test system 200, 300, 400, 800, 900, 1000, and/or 1100) is configured and deployed or utilized to provide interconnects between the DUT 106 and the load board 109. The test system 100 includes, without limitation, a test interconnect assembly 103, a DUT 106, and a load board 109. A first side of the test interconnect assembly 103 is connected to the load board 109. A second side of the test interconnect assembly 103 is connected to the DUT 106. The test interconnect assembly 103 includes DUT interface for connecting to a DUT 106, a load board interface for connecting to a load board 109, and a circuitized component including one or more integrated loopbacks for self-test or self-communication of the DUT 106, and one or more conductive paths for connecting the DUT 106 to the load board 109. In various embodiments, the circuitized component includes a circuit board 209 and/or a circuitized elastomer component 402. Various configurations of the test interconnect assembly 103 (e.g., a test interconnect assembly 203, 303, 403, 803, 903, 1003, and/or 1103) are discussed with respect to FIGS. 1-4 and 8-11.

At step 1204, the test system 100 applies supply voltage(s) and performs test pattern(s) that cause a DUT 106 to perform a self-test function. The supply voltages and test patterns are applied, for example, using the load board 109 and other components such as a power supply and/or the like. The load board 109 can include and/or be connected to the power supply device that provides supply voltages and/or test patterns. The load board 109 can include circuitry configured to apply positive and/or negative supply voltages and test patterns. The test patterns can include inputting analog and/or digital voltage signals to one or more signal nets, reading analog and/or digital voltage signals from the one or more signal nets, and so on.

At step 1206, the test system 100 receives or obtains measurements of various parameters of the test system 100, including self-test measurements. In some embodiments, the test system receives, from the DUT 106 and through the compressible probes 210 or other conductive paths, an indication of a result of a self-test performed by the DUT 106. The test system 100 can also make power measurements including, without limitation, current measurements, voltage measurements, and other measurements. The measurements are made using one or more of the of the compressible probes 210, the integrated conductive paths 410, and/or other conductive paths.

At step 1208, the test system 100 performs a management action such as a self-test management action based on a result of a self-test or loopback functionality, and/or a power management action. The test system 100 can perform a self-test management action and/or a power management action based on the various measurements and corresponding self-test results for the self-test or loopback functionality. A self-test management action can include an additional test pattern, storing a self-test result in a data store, and/or the power management action.

In sum, the disclosed techniques include using a test interconnect such as testing sockets that can include structures to hold a DUT in place for testing. With the disclosed techniques, a self-test function or other type of functions where one input/output connection of the DUT transmits and/or receives from another input/output connection of the DUT is performed using a circuitized component that includes one or more integrated loopbacks for self-test or self-communication of the DUT and one or more conductive paths for connecting the DUT to the load board. The integrated loopbacks are embedded in the circuitized component, so they are much closer to the DUT. In various embodiments, the circuitized component includes a circuitized elastomer component or a circuit board. The test interconnect also includes a DUT interface and a load board interface. Furthermore, some embodiments of the described test interconnect assemblies provide for DUT-side testing using Kelvin probes and other probes that connect to the DUT-side circuit board in various testing locations that can be inside or outside a device footprint.

At least one technical advantage of the disclosed techniques relative to the prior art is that the disclosed techniques enable more accurate DUT self-test and other self-communication functions for testing interconnects. Another technical advantage is a reduction of resistive, capacitive, and/or inductive losses in loopback paths for self-test functions and other self-communication functions of a DUT. The reduction in resistive, capacitive, and/or inductive losses provides higher signal quality and reduced interference in the loopback path. These technical advantages provide one or more technological advancements over prior art approaches. Another technical advantage of the disclosed techniques relative to the prior art is that, with the disclosed techniques, a more accurate measurement of power supply voltage is obtained. Another technical advantage is that power supply integrity is increased. The improved power supply integrity reduces the likelihood of cause electrical damage, heat damage, and/or other damage to the DUT, the test socket, and the load board during testing. These technical advantages provide one or more technological advancements over prior art approaches.

Aspects of the subject matter described herein are set out in the following numbered clauses.
1. In some embodiments, a test interconnect comprises a device under test (DUT) interface for connecting to a DUT, a load board interface for connecting to a load board, a circuitized component comprising one or more integrated loopbacks for self-test or self-communication of the DUT, and one or more conductive paths for connecting the DUT to the load board.
2. The test interconnect of clause 1, wherein the circuitized component comprises a circuit board that provides the one or more integrated loopbacks.
3. The test interconnect of clauses 1 or 2, wherein the circuit board comprises the one or more conductive paths.
4. The test interconnect of any of clauses 1-3, wherein the circuit board comprises one or more grid array vias concentric to a grid array of the DUT, wherein one or more conductive paths correspond to one or more compressible probes that extend through the one or more grid array vias for connection to the DUT.
5. The test interconnect of any of clauses 1-4, wherein the circuitized component comprises an elastomer component that provides at least one of the one or more integrated loopbacks, or the one or more conductive paths using elastomer circuit paths comprising conductive powder.
6. The test interconnect of any of clauses 1-5, wherein the circuitized component comprises one or more passive circuit components.
7. The test interconnect of any of clauses 1-6, wherein the one or more integrated loopbacks connect to the one or more passive circuit components.
8. The test interconnect of any of clauses 1-7, further comprising one or more grid alignment aids for a grid array of the DUT.
9. The test interconnect of any of clauses 1-8, wherein the one or more grid alignment aids include at least one of one or more DUT border alignment guides that are positioned to contact one or more peripheral edges of the DUT, or indents that are positioned to receive solder balls, pins, or other contacts of the DUT.
10. The test interconnect of any of clauses 1-9, further comprising a stiffening plate on a DUT-side surface of the circuitized component, wherein the stiffening plate comprises the one or more grid alignment guides.
11. The test interconnect of any of clauses 1-10, wherein each of the one or more integrated loopbacks is a portion of a loopback circuit that connects a transmitter of the DUT to a receiver of the DUT.
12. The test interconnect of any of clauses 1-11, wherein the circuitized component is disposed between the DUT and the load board, and each of the one or more integrated loopbacks does not connect to the load board.
13. The test interconnect of any of clauses 1-12, wherein the one or more of the integrated loopbacks or the one or more conductive paths includes a conductive powder that becomes conductive when compressed.
14. In some embodiments, a system comprises a load board, and a test interconnect comprising a device under test (DUT) interface for connecting to a DUT, a load board interface for connecting to the load board, a circuitized component comprising one or more integrated loopbacks for self-test or self-communication of the DUT, and one or more conductive paths for connecting the DUT to the load board.
15. The system of clause 14, wherein the circuitized component comprises a circuit board that provides the one or more integrated loopbacks.
16. The system of clauses 14 or 15, wherein the circuitized component comprises an elastomer component that provides at least one of the one or more integrated loopbacks, or the one or more conductive paths using elastomer circuit paths comprising conductive powder.
17. The system of any of clauses 14-16, wherein the circuitized component comprises one or more passive circuit components.
18. The system of any of clauses 14-17, wherein each of the one or more integrated loopbacks is a portion of a loopback circuit that connects a transmitter of the DUT to a receiver of the DUT.
19. The system of any of clauses 14-18, wherein the circuitized component is disposed between the DUT and the load board, and each of the one or more integrated loopbacks does not connect to the load board.
20. In some embodiments, a method for loopback testing of a DUT comprises configuring a test interconnect to include a device under test (DUT) interface for connecting to a DUT, a load board interface for connecting to a load board, and one or more integrated loopbacks for self-test or self-communication of the DUT, applying, using the test interconnect and the load board, a supply voltage and a test pattern that causes the DUT to perform a loopback functionality or a self-test functionality, and performing a management action based on a result of the loopback functionality or the self-test functionality.
21. In some embodiments, a test interconnect comprises a device under test (DUT) interface for connecting to a DUT, a load board interface for connecting to a load board, a circuitized component comprising one or more integrated loopbacks for self-test or self-communication of the DUT, and a Kelvin-type measurement probe that connects to a supply voltage measurement contact.
22. The test interconnect of clause 21, wherein the Kelvin-type measurement probe connects between the supply voltage measurement contact and at least one of a supply voltage measurement contact of the load board, or a cable connection of a testing device.
23. The test interconnect of clauses 21 or 22, wherein the one or more integrated loopbacks include a configured impedance or loss.
24. The test interconnect of any of clauses 21-23, wherein the one or more integrated loopbacks include one or more passive circuit components.
25. The test interconnect of any of clauses 21-24, wherein the one or more integrated loopbacks connect to the one or more passive circuit components.
26. The test interconnect of any of clauses 21-25, wherein the circuitized component comprises a circuit board that provides the one or more integrated loopbacks.
27. The test interconnect of any of clauses 21-26, wherein the circuitized component comprises an elastomer component that provides at least one of the one or more integrated loopbacks, or the one or more conductive paths using elastomer circuit paths comprising conductive powder.
28. The test interconnect of any of clauses 21-27, wherein the supply voltage measurement contact is a contact of a circuit board disposed on a DUT side of the circuitized component.
29. The test interconnect of any of clauses 21-28, wherein the supply voltage measurement contact is a contact of the circuitized component.
30. The test interconnect of any of clauses 21-29, further comprising a stiffening plate on a DUT-side surface of the circuitized component.

Any and all combinations of any of the claim elements recited in any of the claims and/or any elements described in this application, in any fashion, fall within the contemplated scope of the present invention and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments can be embodied as a system, method or computer program product. Accordingly, aspects of the present disclosure can take the form of an entirely hardware embodiment, an entirely software embodiment (including firmware, resident software, micro-code, etc.) or an embodiment combining software and hardware aspects that can all generally be referred to herein as a “module,” a “system,” or a “computer.” In addition, any hardware and/or software technique, process, function, component, engine, module, or system described in the present disclosure can be implemented as a circuit or set of circuits. Furthermore, aspects of the present disclosure can take the form of a computer program product embodied in one or more computer readable medium(s) having computer readable program code embodied thereon.

Any combination of one or more computer readable medium(s) can be utilized. The computer readable medium can be a computer readable signal medium or a computer readable storage medium. A computer readable storage medium can be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium can be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions can be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors can be, without limitation, general purpose processors, special-purpose processors, application-specific processors, or field-programmable gate arrays.

The flowchart and block diagrams in the figures illustrate the architecture, functionality, and operation of possible implementations of systems, methods and computer program products according to various embodiments of the present disclosure. In this regard, each block in the flowchart or block diagrams can represent a module, segment, or portion of code, which comprises one or more executable instructions for implementing the specified logical function(s). It should also be noted that, in some alternative implementations, the functions noted in the block can occur out of the order noted in the figures. For example, two blocks shown in succession can, in fact, be executed substantially concurrently, or the blocks can sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the preceding is directed to embodiments of the present disclosure, other and further embodiments of the disclosure can be devised without departing from the basic scope thereof, and the scope thereof is determined by the claims that follow.

What is claimed is:

1. A test interconnect comprising:
a device under test (DUT) interface for connecting to a DUT;
a load board interface for connecting to a load board;
a circuitized component comprising one or more integrated loopbacks for self-test or self-communication of the DUT; and
one or more conductive paths for connecting the DUT to the load board.

2. The test interconnect of claim 1, wherein the circuitized component comprises a circuit board that provides the one or more integrated loopbacks.

3. The test interconnect of claim 2, wherein the circuit board comprises the one or more conductive paths.

4. The test interconnect of claim 2, wherein the circuit board comprises one or more grid array vias concentric to a grid array of the DUT, wherein one or more conductive paths correspond to one or more compressible probes that extend through the one or more grid array vias for connection to the DUT.

5. The test interconnect of claim 1, wherein the circuitized component comprises an elastomer component that provides at least one of: the one or more integrated loopbacks, or the one or more conductive paths using elastomer circuit paths comprising conductive powder.

6. The test interconnect of claim 1, wherein the circuitized component comprises one or more passive circuit components.

7. The test interconnect of claim 6, wherein the one or more integrated loopbacks connect to the one or more passive circuit components.

8. The test interconnect of claim 1, further comprising one or more grid alignment aids for a grid array of the DUT.

9. The test interconnect of claim 7, wherein the one or more grid alignment aids include at least one of: one or more DUT border alignment guides that are positioned to contact one or more peripheral edges of the DUT, or indents that are positioned to receive solder balls, pins, or other contacts of the DUT.

10. The test interconnect of claim 7, further comprising:
a stiffening plate on a DUT-side surface of the circuitized component, wherein the stiffening plate comprises the one or more grid alignment guides.

11. The test interconnect of claim 1, wherein each of the one or more integrated loopbacks is a portion of a loopback circuit that connects a transmitter of the DUT to a receiver of the DUT.

12. The test interconnect of claim 1, wherein the circuitized component is disposed between the DUT and the load board, and each of the one or more integrated loopbacks does not connect to the load board.

13. The test interconnect of claim 1, wherein the one or more of the integrated loopbacks or the one or more conductive paths includes a conductive powder that becomes conductive when compressed.

14. A system comprising:
a load board; and
a test interconnect comprising:
a device under test (DUT) interface for connecting to a DUT;
a load board interface for connecting to the load board;
a circuitized component comprising one or more integrated loopbacks for self-test or self-communication of the DUT; and
one or more conductive paths for connecting the DUT to the load board.

15. The system of claim 14, wherein the circuitized component comprises a circuit board that provides the one or more integrated loopbacks.

16. The system of claim 14, wherein the circuitized component comprises an elastomer component that provides at least one of: the one or more integrated loopbacks, or the one or more conductive paths using elastomer circuit paths comprising conductive powder.

17. The system of claim 14, wherein the circuitized component comprises one or more passive circuit components.

18. The system of claim 14, wherein each of the one or more integrated loopbacks is a portion of a loopback circuit that connects a transmitter of the DUT to a receiver of the DUT.

19. The system of claim 14, wherein the circuitized component is disposed between the DUT and the load board, and each of the one or more integrated loopbacks does not connect to the load board.

20. A method for loopback testing of a DUT, the method comprising:
configuring a test interconnect to include a device under test (DUT) interface for connecting to a DUT, a load board interface for connecting to a load board, and one or more integrated loopbacks for self-test or self-communication of the DUT;
applying, using the test interconnect and the load board, a supply voltage and a test pattern that causes the DUT to perform a loopback functionality or a self-test functionality; and
performing a management action based on a result of the loopback functionality or the self-test functionality.

21. A test interconnect comprising:
a device under test (DUT) interface for connecting to a DUT;
a load board interface for connecting to a load board;
a circuitized component comprising one or more integrated loopbacks for self-test or self-communication of the DUT; and
a Kelvin-type measurement probe that connects to a supply voltage measurement contact.

22. The test interconnect of claim 21, wherein the Kelvin-type measurement probe connects between the supply voltage measurement contact and at least one of: a supply voltage measurement contact of the load board, or a cable connection of a testing device.

23. The test interconnect of claim 21, wherein the one or more integrated loopbacks include a configured impedance or loss.

24. The test interconnect of claim 21, wherein the one or more integrated loopbacks include one or more passive circuit components.

25. The test interconnect of claim 24, wherein the one or more integrated loopbacks connect to the one or more passive circuit components.

26. The test interconnect of claim 21, wherein the circuitized component comprises a circuit board that provides the one or more integrated loopbacks.

27. The test interconnect of claim 21, wherein the circuitized component comprises an elastomer component that provides at least one of: the one or more integrated loopbacks, or the one or more conductive paths using elastomer circuit paths comprising conductive powder.

28. The test interconnect of claim 21, wherein the supply voltage measurement contact is a contact of a circuit board disposed on a DUT side of the circuitized component.

29. The test interconnect of claim 21, wherein the supply voltage measurement contact is a contact of the circuitized component.

30. The test interconnect of claim 21, further comprising:
a stiffening plate on a DUT-side surface of the circuitized component.
